(19) United States
(12) Patent Application Publication
(10) Pub. No.: US 2023/0176092 A1
(43) Pub. Date: Jun. 8, 2023

(54) JIG FOR MANUFACTURING PROBE CARD, PROBE ALIGNMENT SYSTEM COMPRISING SAME, AND PROBE CARD MANUFACTURED THEREBY

(71) Applicants: Oug Ki LEE, Seoul (KR); PHICOM CO., LTD., Bucheon-si, Gyeonggi-do (KR)

(72) Inventor: Oug Ki LEE, Seoul (KR)

(21) Appl. No.: 17/916,544

(22) PCT Filed: Mar. 23, 2021
(86) PCT No.: PCT/KR2021/003603

§ 371 Date: Sep. 30, 2022

(30) Foreign Application Priority Data
Apr. 3, 2020 (KR) 10-2020-0041111

(51) Int. Cl. G01R 3/00; G01R 1/073

(52) U.S. Cl. CPC G01R 3/00; G01R 1/07314

(57) ABSTRACT

The present disclosure provides a jig for manufacturing probe card for semiconductor inspection, a probe alignment system comprising same, and a probe card manufactured thereby.

### BACKGROUND

### Technical Field

This disclosure relates to a jig for manufacturing a probe card for semiconductor inspection, a probe alignment system comprising the same, and a probe card manufactured thereby.

### Description of the Related Art

Before proceeding with the semiconductor assembly process or after the semiconductor packaging is finally performed, electrical die storing (EDS, or packaging test) is performed to check whether hundreds to thousands of semiconductor chip pads made on a wafer or packaged semiconductors have desired electrical characteristics. A device called a probe card is used to inspect electrical characteristics of a chip in the semiconductor or the wafer.

In the probe card inspection, a connector mounted on the probe card, for example, by physically contacting a probe, also referred to as a probe needle, a probe tip or a probe lead, to the surface of a chip pad arranged on the wafer, and by passing a specific current signal through the probe, the electrical and functional characteristics at that time are measured.

Meanwhile, as semiconductors are highly integrated, the number of chip pads on a wafer is increasing, and the spacing and size are also decreasing. Accordingly, in order for probe cards to correspond thereto, there is a trend in which probes are arranged at minute intervals.

### BRIEF SUMMARY

In order to prevent electrical interference and short between probes adjacent to each other, probes of a probe card should be arranged while securing a minimum separation distance. Due to the conflicting requirements, it is a challenge to improve a structure of a probe and the arrangement of probes to accurately contact a fine-pitched pad in the related art.

In another aspect, a plurality of probes should be in contact with chip pads at positions corresponding to test coordinates at the same time to have electrical connection, but some probes may fail in connection. The main causes are a contact point error due to the structural deformation of a probe and contact resistance due to an oxide film formed on a chip pad.

Typically, a high-resistance oxide film is formed on a surface of a chip pad. For this reason, a tip of a probe must directly contact a conductive layer on the surface of the chip pad while removing at least a portion of the oxide film on the surface of the chip pad. However, for example, when the tips of the probes face the surface of the chip pad, due to the plurality error of the tips of the plurality of probes or the plurality error of the surface of the chip pad, an arbitrary probe may have a tip that is closer to the chip pad while a tip of another arbitrary probe may not contact the chip pad, or even if a tip of a probe contacts the chip pad, the tip of the probe may not contact the conductive layer of the chip pad because of a oxide film not sufficiently being removed.

Therefore, in order to ensure the contact reliability between probes and a chip pad, required is overdrive, making a stable electrical contact between the probes and the chip pad by pressing tips of the probes to move further in the direction of the chip pad after the probes contact the chip pad. More precisely, overdrive refers to additional pressure at the point where the probes make contact with the chip pad.

Since planarity indicating a step difference between a plurality of probes that inevitably occurs, overdrive may be applied to a minimum. This is because repeated application of overdrive of a certain size or larger may cause structural deformation on a probe in a probe card or damage to a conductive layer of a chip pad.

As such, it is beneficial to have a probe card that does not impair the quality of a semiconductor and a technology capable of implementing the same by making the planarity of tips of probes so that the probes may easily contact desired positions on the semiconductor.

One or more embodiments of the present disclosure provide a jig for manufacturing a probe card, a probe alignment system comprising the same, and an alignment apparatus, for solving the various technical problems in the related art including the technical problem described above.

According to an aspect of the present disclosure, a jig of the present disclosure for manufacturing a probe card includes a guide hole plate including a plurality of guide holes having the same arrangement as the arrangement of test coordinates, and a reference plate on which the guide hole plate and probes may be seated.

Using the jig, in the stage before assembling the probe card, a plurality of probes introduced into the guide holes may be aligned in the same arrangement as the test coordinates, and the probes may be simultaneously mounted on a microprobe head (MPH) in an aligned state at a level that minimizes planarity. Thus, the process efficiency of the probe card may be greatly improved.

In addition, the jig according to the present disclosure may align tips of the plurality of probes to be on the same line based on the structure thereof. Therefore, when a probe card is manufactured using the jig of the present disclosure, the heights of the tips of all probes constituting the card may be relatively uniform, and thereby even under the reduced overdrive method, a probe card that allows all probes to effectively contact the test object may be implemented.

Furthermore, the jig according to the present disclosure may couple and bond all the probes to the MPH at the same time in a state where the probes of the probe card exactly match the test coordinates and the tips of the probes are uniformly aligned. Thus, an effective and economical probe card may be implemented.

According to the aspect, the above-mentioned conventional problems may be solved, and the present disclosure has a practical object to provide specific example embodiments thereof and various example embodiments to which the problems are applied.

According to an aspect, there is provided a jig for manufacturing a probe card configured to erect a plurality of probes at predetermined positions, and to couple the probes to a MPH in an upright state at the predetermined positions.

According to an aspect,

there is provided a jig of manufacturing a probe card, the jig which is configured to make a plurality of probes upright at predetermined positions and to couple the probes to a micro probe head (MPH) in an upright state at the predetermined positions, and the jig includes

a guide hole plate having test coordinates corresponding to positions of a plurality of pads arranged on a wafer or a semiconductor chip, and having a plurality of guide holes respectively accommodating the probes at positions of the test coordinate, and

a reference plate that the guide hole plate is detachably coupled on, that tips of the probes introduced through the guide holes are seated on, and that supports the probes in the upright state along with the guide holes,

wherein the guide hole plate induces introduction and separation of the probes along inner surfaces of the guide holes, so that the probes introduced into the guide holes are bonded to the MPH at the positions and then separated along the guide holes.

In a non-limiting example embodiment,

The guide hole plate may include a lower surface that is closest to a ground when positioned parallel to the ground, an upper surface opposite to the lower surface, and a side surface extending along outer periphery of the supper surface and the lower surface and connecting the upper surface and the lower surface.

The guide hole may be hollow communicating vertically from the upper surface to the lower surface including a first opening part formed on the upper surface, a second opening part formed on the lower surface and an inner surface extending between outer periphery of the first opening part and the second opening part, and depending on the shape of the probe to be inserted. The guide hole may be circular, triangular, rectangular or square with respect to the plane.

The reference plate may be closely attached to the lower surface to seal the second opening part so that a probe introduced through the first opening part does not pass through the second opening part and be left from the guide hole plate, and sets an internal space of an open shape with only the first opening part together with the inner surface.

In a non-limiting example embodiment, the probe introduced through the first opening part may be lowered toward the second opening part while in contact with at least a part of the inner surface.

In a non-limiting example embodiment, a supporting part protruding outwardly from a fore end of the probe may span one area of the outer periphery of the first opening part.

In a non-limiting example embodiment, all guide holes formed in the one guide hole plate may have a same shape of one of a circle, a triangle, a square and a rectangle, and have a same shape and area in transverse cross section from the first opening part to the second opening part.

In a non-limiting example embodiment, when the probe is inserted into the guide hole, a tip of the probe may be in contact with the reference plate through the second opening part to be maintained in an upright state in the internal space.

In a non-limiting example embodiment, when the probe is maintained in the upright state, a depth of the guide hole relative to a height of the upright probe may be about 70% to 99.9% so that a part of the fore end side of the probe protrudes through the first opening part.

In a non-limiting example embodiment, the guide hole plate may include a material that is not attracted to a magnet.

In a non-limiting example embodiment, a metal coating layer that is attracted to a magnet may be formed on the lower surface of the guide hole plate, the metal coating layer being absent in the inner surface of the guide hole.

In a non-limiting example embodiment, the metal coating layer may include at least one selected from a group consisting of nickel, iron, cobalt, tungsten and stainless steel, or an alloy of two or more selected from the group.

In a non-limiting example embodiment, the guide hole plate may include a magnetic body that is attracted to a magnet. In this case, the guide hole plate may not include the metal coating layer. Conversely, the guide hole plate may include the metal coating layer.

In a non-limiting example embodiment, at least a part of the outer periphery of the first opening part may be chamfered to have a tapered inclined structure.

In a non-limiting example embodiment, the guide hole plate and the reference plate each may be made of a material having a thermal expansion coefficient of 90% to 100%, specifically 95% to 100%, more specifically 97% to 99.9%, further more specifically 99% to 99.9%, with respect to the MPH and/or the wafer or the semiconductor chip in which a circuit for inspecting the wafer or the semiconductor chip is formed.

In a non-limiting example embodiment, the material may include silicon, a ceramic-based material and/or a metal-based material.

The metal-based material may include SUS 304, SUS 420 series, Invar, Kovar, Novinite, and alloys thereof.

The ceramic-based material may include low temperature co-fired ceramic (LTCC), alumina and mullite.

In an un-limited example embodiment,

the reference plate may include:
a seating part in which the guide hole plate is seated in a state of facing the lower surface of the guide hole plate,
a bottom surface that is opposite to the seating part,
a magnet built-in part in the reference plate, in which one or more magnets are formed in order for magnetic force to act evenly on all of the seating part of the reference plate, and
a magnet detachably mounted to the magnet built-in part.

In a non-limiting example embodiment, the reference plate may further include one or more inlets communicating in a vertical direction from the seating part to the bottom surface.

In a non-limiting example embodiment, each of the inlets may have one open side formed in the seating part that is located on the lower surface of the guide hole plate where the second opening part of the guide hole does not exist, and take air into the other open side to form a negative pressure therein.

The guide hole plate may be close contact with the seating part by the negative pressure formed in the inlet.

In a non-limiting example embodiment, the magnet may pull the guide hole plate in a vertical direction to closely contact the seating part.

The guide hole plate and the reference plate may be fixed to each other by the magnetic force of the magnet.

In a non-limiting example embodiment, the magnet may maintain magnetic force even at a temperature of 400 degrees Celsius (° C.) or higher, move the probe introduced into the guide hole by magnetism at room temperature to the seating part and prevent a shaking of the probe supported by the seating part.

In a non-limiting example embodiment, the magnet may lose its magnetic force at a temperature of 300° C. or higher, move the probe introduced into the guide hole by magnetism at room temperature to the seating part, and prevent a shaking of the probe supported by the seating part.

In a non-limiting example embodiment, a clamping member for mechanically fixing the guide hole plate and the reference plate may be further included.

According to another aspect, there is provided a probe alignment system that includes a jig configured to align probes so that a plurality of probes are accommodated in guide holes formed at predetermined positions to make the probes stand upright and the probes are coupled to the MPH from the guide holes in an upright state.

The probe alignment system includes a probe storage configured to accommodate one or more upright probes arranged in one direction and supply the probes to the guide holes so that the probes are inserted into the guide holes in an upright state.

The components and structure of the jig may be the same as those of the above-described example embodiments, and without limitation, the jig may include a guide hole plate that includes a plurality of guide holes formed to accommodate probes at positions corresponding to test coordinates of a wafer or a semiconductor chip and induces introduction and separation of the probes along inner surfaces of the guide holes, so that the probes introduced into the guide holes are bonded to the MPH at the positions and then separated along the guide holes.

The jig may include a reference plate that the guide hole plate is detachably coupled to the reference plate and a tip of the probe introduced through the guide holes is seated on the reference plate so that the reference plate supports the probes along with the guide holes to make the probes stand upright state. Here, the components and structures of the guide hole plate and the reference plate may be the same as those of the example embodiments described above, respectively.

In a non-limiting example embodiment, the probe storage may include:

a magazine configured to accommodate therein a probe arrangement structure which is one probe or two or more probes being arranged in a line by sides of the probes being in contact, and

a feeding part configured to continuously feed probes into the magazine one by one,

wherein the feeding part may be connected at one side of the magazine, and a probe positioned at an outermost side on the other side is left from the magazine and is inserted into a guide hole, and

wherein, when the probe is left from the other side, the probe arrangement structure including a probe supplied from the feeding part may be constituted so that probes are sequentially moved to the other side.

In a non-limiting example embodiment, the magazine may include:

a side plate positioned on the other side,

a connection part positioned on the one side and connected to the feeding part, and one or more support bodies extending between the side plate and the connection part and supporting a probe so that the probe moves stably in its extension direction,

wherein a probe supplied from the feeding part may move from one side to the other side along the support bodies.

In a non-limiting example embodiment,

when a probe is left from other side, the probes may be sequentially moved to the other side by a probe supplied from the feeding part, and a probe positioned at an outermost side may be supported in contact with an inner surface of the side plate, and the probe supplied from the feeding part may move from one side to the other side with pressurizing, and the probe arrangement structure may be arranged in a line in the one direction to maintain an upright state.

In a non-limiting example embodiment, the connection part may include a pressing means configured to press a probe in a direction from the one side to the other side to smoothly move the probe,

and a probe supplied from the feeding part may be supplied between the pressing means and a probe adjacent to the probe, and when the probe is left from the other side, the pressing means may press the probe supplied from the feeding part in the direction from the one side to the other side so that probes are sequentially moved to the other side, here, a probe positioned at an outermost side may be supported in contact with an inner surface of the side plate, and while the pressing means presses probes in the direction from one side to the other side, the probe arrangement structure may be arranged in a line in the one direction to maintain an upright state.

The pressing means may be, for example, a screw member or a spring member.

In a non-limiting example embodiment,

the support bodies may include:
at least one first support body facing a first side surface of the probe, and
at least one second support body facing a second side surface of the probe,
wherein a supporting part protruding in a direction of the second side surface may be formed at a fore end of the probe, and the supporting part may span an end of the second support body, and
each of the first support body and the second support body may extend between the side plate and the connection part, and may be coupled to the side plate and the connection part.

In a non-limiting example embodiment, the side plate may include a first indented part that is indented from one side to the other side to form an inner surface of the side plate, and form open outlets at an upper end and a lower end.

A probe accommodated in the first indented part may be slid downward or upward along the first indented part by an external force and be separated to the upper end or the lower end of the outlets.

In a non-limiting example embodiment, the side plate may be equipped with a magnet for magnetically fixing the probe accommodated in the first indented part on an outer surface opposite to the first indented part.

In a non-limiting example embodiment, the side plate may include a second indented part indented in a direction of an end facing an upper end adjacent to the outlet and/or a lower end adjacent to the outlet so that a fore end or a tip of the probe accommodated in the first indented part from the outside of the side plate may be exposed to the outside.

In a non-limiting example embodiment, the feeding part may be a vibration feeder.

According to another aspect, there is provided a probe alignment apparatus.

In a non-limiting example embodiment, the probe alignment apparatus includes:

a main frame as a frame with a plurality of beams assembled,

a vacuum pump detachably mounted to the main frame,

a plate with rectangular shape detachably mounted to the main frame,

an arm member detachably mounted on the main frame and comprising a first arm extending in a direction perpendicular to the plate and a second arm extending in parallel to the plate while being perpendicular to the first arm,

a jig provided in the main frame to align the probes so that the plurality of probes are accommodated in guide holes formed at predetermined positions to make the probes stand upright, and from the guide holes, the probes are bonded to the MPH in an upright state,

a probe storage that accommodates a plurality of upright probes arranged in a line in one direction so that the probes are inserted into the guide holes in an upright state, and is positioned so that the probes are supplied to the guide holes,

a first stage mounted on the plate of the main frame to align the jig to the insertion position of a probe to be discharged from the probe storage in an arbitrary guide hole by moving the jig left and right, forward and backward, and rotating axially,

a probe carrier configured to insert a probe positioned at an outermost side among probes accommodated in the probe storage into the guide hole,

an actuator to which the probe carrier is mounted and which moves the probe carrier,

a second stage to which the actuator is mounted in a state of being mounted on the arm member, and that moves the probe carrier mounted on the actuator to an insertion or extraction position of a probe to be ejected from the probe storage by moving the actuator back and forth, left and right and up and down,

a fastening part configured to mechanically mount the probe storage to the main frame or the second stage,

a vision part configured to identify the probe arranged at the outermost side among the probes accommodated in the probe storage and a guide hole where the probe to be inserted,

a monitoring part configured to display an image identified by the vision part, and

a controlling part comprising a computer in which a predetermined program is embodied to control operations of the jig, the first stage, the second stage, the actuator, the vision part, the monitoring part, and/or the probe storage and a coordinate movement of the input guide hole.

In a non-limiting example embodiment, the fastening part may be coupled to the probe storage to fix the probe storage to the main frame in a state where the fastening part is coupled to the main frame. In a non-limiting example embodiment related thereto, the probes accommodated in the probe storage may be left from the magazine of the probe storage by a probe carrier in the form of a hollow inhaler.

In a non-limiting example embodiment, the fastening part may be coupled to the probe storage to fix the probe storage to the second stage while being coupled to a part of the second stage. In one non-limiting example related thereto, the probes accommodated in the probe storage may be left from the magazine of the probe storage by the probe carrier in the form of a blade, a prismatic or rod-shaped pin.

In a non-limiting example embodiment, the vision part may be configured to identify a tip and a fore end of the probe arranged at an outermost side among the probes accommodated in the probe storage and provide information on a distance calculated by identifying coordinates of the guide hole in which the probe is to be inserted, to the controlling part comprising the computer in which the predetermined program is embodied.

The controlling part may process the information provided from the vision part to determine whether the probe carrier is accurately positioned at the position of the probe arranged at the outermost side among the probes.

In a non-limiting example embodiment, the second arm may be positioned at a top of the first stage.

The second stage may be detachably mounted on an end of the second arm to face the first stage at an upper part of the first stage.

In a non-limiting example embodiment, the second stage may include:

based on a cube having a Z-axis representing a height, an X-axis representing a length, and a Y-axis representing a width,

a first plate having two or more first guide rails extending in the Z-axis installed and detachably mounted to the arm member,

a second plate including a vertical part complementarily engaged with the first guide rails to slide along the first guide rails in the Z-axis direction, and a horizontal part extending vertically from the lower end of the vertical part in the Y-axis direction and having two or more second guide rails extending in the X-axis at the lower end,

a third plate complementarily engaged with the second guide rails to slide along the second guide rails in the X-axis direction and having two or more third guide rails extending in the Y-axis at the lower end, and

a fourth plate that is complementarily engaged with the third guide rails to slide along the third guide rails in the Y-axis direction, on which the actuator is mounted on a lower front side, of which the vision part is mounted on one side, and in which a fastening member is formed at the other side to fasten the fastening part in which the probe storage is fastened.

In a non-limiting example embodiment, the vision part may be mounted on a side surface of the fourth plate corresponding to the X-axis, and in the direction of the X-axis, and the vision part may be configured to identify a tip and a fore end of the probe arranged at an outermost side among the probes accommodated in the probe storage and provide information on a distance calculated by identifying coordinates of the guide hole in which the probe is to be inserted, to the controlling part comprising the computer in which the predetermined program is embodied.

The controlling part may determine by the vision part whether the probe carrier is accurately positioned at the position of the guide hole into which the probe arranged at the outermost side among the probes is to be inserted.

In a non-limiting example embodiment, the actuator may be a cam motion actuator including a rotation shaft and a cam or an electronic actuator that moves up and down.

In a non-limiting example embodiment, the probe carrier may be a blade or prismatic or rod-shaped pin, which pushes down the probe arranged at the outermost side accommodated in the probe storage in response to a movement of the second stage and/or the actuator to separate the probe from the probe storage and guide the probe to be inserted into the guide hole.

After the probe is inserted, the probe carrier may be applied by a control program to which restoring force for restoring vertically upward is input.

In a non-limiting example embodiment, the probe carrier may be a hollow inhaler that separates the probe upward from the probe storage in response to the movement of the second stage and/or the actuator while the probe is fixed by forming a negative pressure inside in a state in which a fore end of the probe is in surface contact with the probe carrier.

In a non-limiting example embodiment, the inhaler in contact with the fore end may have ends including a first end that is in contact with a surface of the fore end and a second end that is perpendicular to a boundary of the first end and extends downward, and is in contact with a side surface adjacent to the surface of the fore end.

The first end may suck the surface of the fore end, and the second end may suck the side surface adjacent to the surface of the fore end.

In a non-limiting example embodiment, the first stage may include:

based on a plane parallel to a ground and having a X-axis representing a length and a length Y-axis representing a width, and

a θ-axis driving part to which the jig is mounted, and that rotates the jig in a θ direction, an X-axis driving part to which the θ-axis driving part is mounted, and that moves the θ-axis driving part along the X-axis, and a Y-axis driving part that moves the θ-axis driving part along the Y-axis.

In a non-limiting example embodiment, the probe carrier may selectively use one of a blade, a pin, and a hollow inhaler depending on a situation.

In a non-limiting example embodiment, operation of the probe alignment apparatus may be identified and recognized by the vision part, and the controlling part, with identification and recognition by the vision part, may control the insertion of the probe into the guide hole of the jig to proceed sequentially according to a program including predetermined information and test coordinate insertion order and a control logic thereof.

According to another aspect, there is provided a method for manufacturing a probe card using the probe alignment system or the probe alignment apparatus.

The method includes:

fabricating probes,

preparing and combining a guide hole plate and a reference plate,

entering coordinates of a plurality of guide holes to insert the probes and the insertion order,

inserting a plurality of probes for contacting a test circuit of a wafer or semiconductor chip having predetermined test coordinates into a plurality of guide holes formed at positions corresponding to the test coordinates, respectively,

preparing a MPH in which a plurality of circuits for inspecting the wafer or semiconductor chip are formed at the positions corresponding to the test coordinates,

adding a conductive paste adhesive to each circuit of the MPH,

aligning the MPH with the guide hole plate so that fore ends of the probes inserted to correspond to the test coordinates and the circuits of the MPH formed to correspond to the test coordinates face each other,

manipulating the plurality of probes to be adhered upright on the circuits of the MPH by facing and contacting the MPH with an upper end surface of the guide hole plate so that the fore ends of the probes and the circuits of the MPH are in contact,

performing a reflow process on the adhered circuit and the probes to bond the circuit and the probes,

sequentially separating a magnet, the reference plate, and the guide hole plate from the MPH to which the probes are bonded,

coupling the MPH with a main printed circuit board, the MPH and the main printed circuit board being electrically interconnected by electronic components and interposers, and

attaching a plurality of connectors for connecting a plurality of electrical components corresponding to characteristics of the wafer or semiconductor chip to be tested and the probe card and a probe station, and fastening the deformation prevention mechanism apparatus.

According to another aspect, there is provided a vertical micro-electro-mechanical systems (MEMS) probe card manufactured using the method.

### Effects

According to the example embodiments, there is provided a jig that includes a guide hole plate including a plurality of guide holes having the same arrangement as the arrangement of test coordinates, and includes a reference plate on which the guide plate and probes may be seated.

Using the jig, in the stage before assembling the probe card, the plurality of probes introduced into the guide holes may be aligned in the same arrangement as the test coordinates, which is significantly improved compared to a conventional alignment form. After that, the probes may be simultaneously mounted on the MPH in the aligned state. Thus, the process efficiency and lifespan of the probe card may be greatly improved.

Further, based on the jig structure of the present disclosure, a plurality of tips of the probes may be aligned so that the tips are on the same line. Thus, the planarity may be improved.

The probe alignment system and apparatus according to the present disclosure may quickly insert a plurality of probes into guide holes based on the structure of the probe storage constituting them. Accordingly, the probe alignment system and apparatus of the present disclosure may greatly improve the manufacturing efficiency, quality and lifespan of the probe card.

### BRIEF DESCRIPTION OF THE SEVERAL VIEWS OF THE DRAWINGS

FIG. 1 is an exploded schematic view of a guide hole plate and a reference plate, which are a jig for manufacturing a probe card according to an example embodiment of the present disclosure.

FIG. 2 is a vertical cross-sectional schematic view of the jig shown in FIG. 1.

FIG. 3 is an enlarged schematic view of the guide hole plate shown in FIG. 1

FIGS. 4A and 4B illustrate schematic views of a probe inserted into a guide hole shown in FIG. 1.

FIGS. 5A and 5B illustrate schematic views of an example probe of the present disclosure.

FIG. 6 is a schematic view showing that another example probe of the present disclosure is inserted into a guide hole.

FIG. 7 is a schematic view showing that another example probe of the present disclosure is inserted into a guide hole.

FIG. 8 is a vertical cross-sectional schematic view of a jig for manufacturing a probe card according to another example embodiment of the present disclosure.

FIG. 9 is a schematic view of a probe alignment system according to an example embodiment of the present disclosure.

FIGS. 10A and 10B are schematic views of a magazine of the present disclosure.

FIG. 11 is a schematic view of a vertical section of the magazine of the present disclosure.

FIG. 12 is an enlarged schematic view of a part of the magazine of the present disclosure.

FIG. 13 is a schematic view of a first indented part of a side plate constituting the magazine of the present disclosure.

FIG. 14 is an enlarged schematic view of a part of the magazine of the present disclosure.

FIG. 15 is a schematic view of a probe alignment apparatus according to an example embodiment of the present disclosure.

FIG. 16 is a schematic view of an arm member and a second stage of the present disclosure.

FIG. 17 is a schematic view of a first stage of the present disclosure.

FIGS. 18A and 18B illustrate schematic views showing operation of an actuator, a probe carrier and a probe storage according to an example embodiment of the present disclosure.

FIG. 19 is a schematic view illustrating operation of a second stage, an actuator, a probe carrier and a probe storage according to an example embodiment of the present disclosure.

FIG. 20 is a vertical cross-sectional schematic view of the probe carrier shown in FIG. 19.

FIG. 21 is a schematic view of a part of a probe alignment apparatus according to another example embodiment of the present disclosure.

FIG. 22 is another schematic view of a part of the probe alignment apparatus shown in FIG. 21.

FIG. 23 is a schematic view of a probe card according to an example embodiment of the present disclosure.

### DETAILED DESCRIPTION

Hereinafter, example embodiments of the present disclosure will be described in more detail with respect to in order of “a jig for manufacturing a probe card,” “a probe alignment system” and “a probe alignment apparatus” according to the present disclosure.

Prior to describing the present disclosure in detail, terms or words used in the present disclosure and claims should not be construed as being limited to conventional or dictionary meanings, and the terms and words should be interpreted as meaning and concept consistent with the technical idea of the present disclosure based on the principle that an inventor can appropriately define the concept of the terms and words in order to best describe his/her disclosure.

Therefore, the embodiments described in the present disclosure are only example embodiments, and the example embodiments described in the present disclosure do not represent all the technical spirit of the present disclosure, it should be understood that various equivalents and modifications that can be substituted for them may exist at the time of the application of the present disclosure.

In this specification, a singular expression includes a plural expression unless context clearly dictates otherwise. In the present disclosure, terms such as “include,” “comprise” and “have” are intended to designate the existence of embodied features, numbers, steps, components or combinations thereof. It should be understood that the terms do not preclude the possibility of addition or existence of one or more other features or numbers, steps, elements or combination thereof.

As used herein, the term “vertical direction” broadly refers to the direction in which gravity acts, and more specifically, refers to the direction in which the thread is directed when an arbitrary object is hung on the thread on the ground having a predetermined area. Briefly, the term “vertical direction” indicates a direction perpendicular to the ground.

The term “bending” used herein refers to a state in which an object is bending or bent in a predetermined direction so that the object has a curved surface. Alternatively, a term “curve” may be used.

The term “probe” used herein refers to a pin, a conducting wire or a bar extending to a predetermined length, to be connected to an electric/electronic circuit board or component to electrically connect the board or a component to another external apparatus. In more detail, the probe may be a device for inspecting the characteristics of a chip pad of a semiconductor or a wafer. For example, the probe may be a member that is physically coupled and electrically connected to a circuit board constituting a probe card, and in this state, the probe may be physically contacted and electrically connected to a chip pad of a semiconductor or a wafer to conduct electricity and communicate between the circuit board and the chip pad.

The term “surface of a wafer” or “surface of a chip pad” used herein refers to a conductive layer, forming the outer surface of a wafer body or chip pad underneath while in contact with an oxide film, except for an oxide film that is relatively difficult to conduct electricity, formed on the wafer or the chip pad. When the probe of the present disclosure is in contact with the “surface of the wafer” or the “surface of the chip pad,” it may be understood that a tip of probe is contact with the outer surface of the wafer body under the oxide film by removing at least a part of the oxide film, and the abutting position may be understood as a position corresponding to a chip capable of electrically interacting with a probe by contacting among a plurality of chips included in the wafer.

In the present disclosure, the term “fore end” may refer to one end of an object or an object matter or the direction toward the end, with respect to an arbitrary reference direction. The term “tip” may refer to the other end or a direction toward the other end with respect to the arbitrary reference direction. In this case, the “fore end” may include an object or a portion that is very adjacent to an end, a distal end, and/or an end surface of the object. The “tip” may include a distal end, an end and/or a portion positioned very adjacent to the end and the distal end. The fore end and the tip may be perceived as a pair, and may be distinguished from other ends, distal ends and/or portions positioned very adjacent to the ends and the distal ends.

### Jig for Probe Card Manufacturing

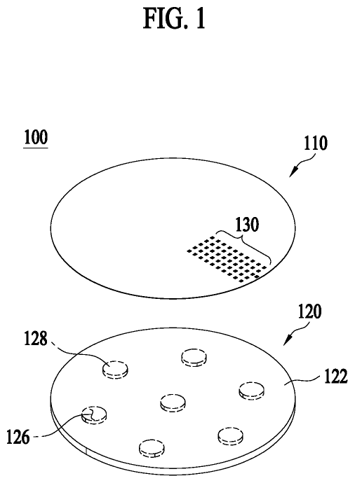

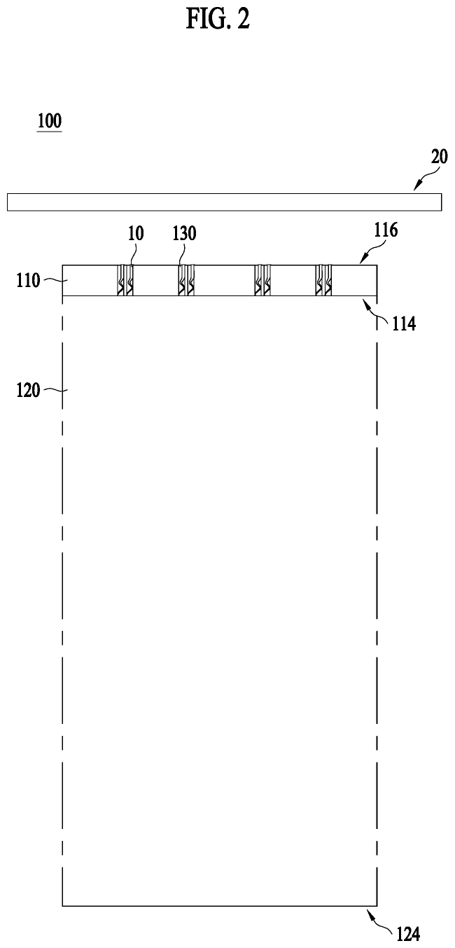

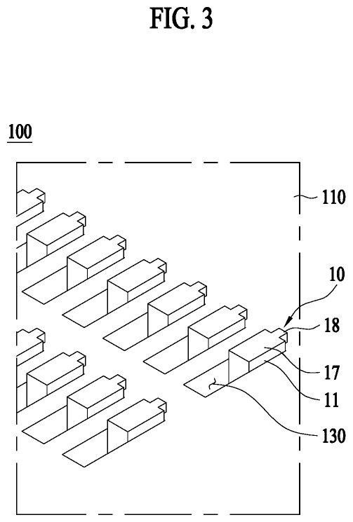

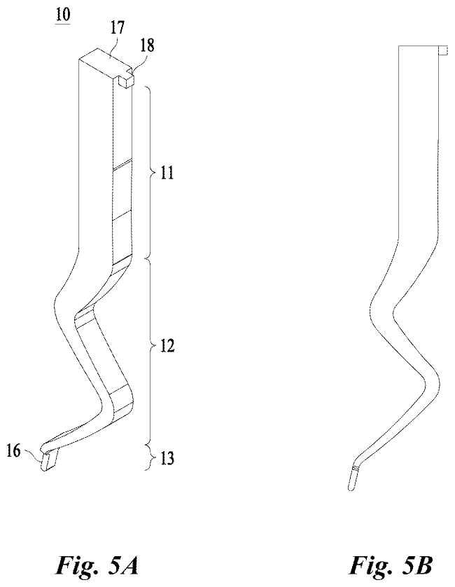

FIGS. 1 to 7 are schematic views for specifically illustrating the structure of a jig for manufacturing a probe card according to an example embodiment of the present disclosure. For reference, the structure and functions of the jig of the present disclosure will be described in detail with reference to an example probe 10 shown in FIGS. 5A and 5B. However, the probe 10 of FIGS. 5A and 5B is only an example embodiment applicable to the unitization and application of the jig according to the present disclosure, and it is not that the jig of the present disclosure is applicable only to the probe 10 of the illustrated type and is optimized for the probe 10.

The probe 10 is coupled with a microprobe head (MPH) 20 to constitute a probe card. The MPH 20 is a ceramic-based substrate so that one side is connected to a main printed circuit board, and on the other side, a number of probes are collectively bonded with high heat. A circuit for inspecting a wafer or a semiconductor chip is formed according to semiconductor characteristics. An electrical path of the probe card is formed by the circuit of the MPH 20 and the probe 10 connected to the circuit.

The example probe 10 includes an upright connection part 11, an elastic part 12 and a tip part 13. The upright connection part 11 extends vertically downward with respect to the MPH 20 so as to be vertically mounted on the MPH 20, and a supporting part 18 of a structure protruding to be horizontal with respect to the MPH 20 is formed at the uppermost end of the upright connection part 11. The elastic part 12 is integrally formed with the upright connection part 11 and extends downward. The elastic part 12 is bent twice to be elastically deformable with respect to an external force in the vertical direction, and is provided to distribute and absorb the pressure applied to the tip part. The tip part 13 is integrally formed with the elastic part 12 and extends downward, and is provided to contact a central portion of a pad of a wafer or semiconductor chip.

A jig 100 serves to manufacture a probe card, which is in particular aligning the probe 10 to be easily coupled to the MPH 20. The jig 100 includes a guide hole plate 110 and a reference plate 120.

In general, a plurality of pads whose characteristics are to be inspected in a wafer or a semiconductor chip are arranged at intervals that are different, complex and minute depending on the circuit structure.

In the present disclosure, positions at which pads are arranged are referred to as test coordinates. Conventionally, each of the probes 10 is mounted one by one on a circuit board of a probe card or the MPH 20 to correspond to test coordinates. However, it takes a considerable amount of time, and there is a problem in that planarity and alignment with respect to tips 16 of the probes 10 in the completed probe card are not relatively uniform. This non-uniform planarity is a major cause of excessive overdrive in the inspection using the probe card, and thus it needs to be improved.

The guide hole plate 110 includes a plurality of guide holes 130 for accommodating the probes 10, respectively. The guide holes 130 are formed at positions corresponding to the test coordinates of a wafer or a semiconductor chip. The guide hole plate 110 is provided to induce introduction and separation of the probes 10 along inner surfaces of the guide holes 130 formed in the guide hole plate 110, and thus after the probes 10 inserted into the guide holes 130 are coupled to the MPH 20 at positions, the probes 10 are separated along the guide holes 130.

The guide hole plate 110 and the reference plate 120 may be made of a material having a thermal expansion coefficient close to that of the MPH 20 in which a circuit for inspecting a wafer or a semiconductor chip is formed, or the same material. This is to prepare for thermal deformation when the MPH 20 is coupled with the probes 10 mounted on the jig 100. This is because, if the coefficients of thermal expansion are significantly different, the probes 10 may not be mounted and/or contacted at desired positions of the MPH 20 and the semiconductor chip pad.

The material constituting the guide hole plate 110 may include, but is not limited to, silicon, a ceramic-based material, and/or a metal-based material. The metal-based material may include SUS 304, SUS 420 series, Invar, Kovar, Novinite and their alloys. The ceramic-based material may include silicon, low temperature co-fired ceramic (LTCC), alumina and mullite.

The reference plate 120 may be made of iron or stainless steel.

The guide hole plate 110 includes a lower surface 114 closest to the ground based on a state positioned parallel to the ground, an upper surface 116 opposite to the lower surface 114, and a side surface extending along the outer periphery of the upper surface 116 and the lower surface 114 and connecting the upper surface 116 and the lower surface 114. The lower surface 114 may be plated with a metal material attracted by magnetic force.

The reference plate 120 is a flat plate on which the guide hole plate 110 is seated. Further, the tips 16 of the probes 10 introduced through the guide holes 130 of the guide hole plate 110 may be seated on the reference plate 120, so that the reference plate 120 may support the probes 10 together with the guide holes 130 in the upright state.

The reference plate 120 includes a seating part 122 in which the guide hole plate 110 is seated in a state facing the lower surface 114 of the guide hole plate 110, a bottom surface 124 which is the opposite surface of the seating part 122, a magnet built-in part 126 provided to receive one or more magnets 128 therein, and the magnets 128 mounted to the magnet built-in part 126.

As described above, the guide hole plate 110 of the jig 100 according to the present disclosure includes a plurality of guide holes 130 having the same arrangement as the arrangement of the test coordinates. Therefore, using the jig 100 according to the present disclosure, the plurality of probes 10 introduced into the guide holes 130 may be aligned in the same arrangement as the test coordinates of the semiconductor chip before assembling the probe card, and thereafter, the probes 10 may be simultaneously mounted on the MPH 20 in the aligned state. Thus, the efficiency of the manufacturing process of a probe card may be greatly improved.

Further, the jig 100 according to the present disclosure may align the tips 16 of the plurality of probes 10 to be on the same line based on the structure. Thus, the planarity may be improved.

Specifically, the tips 16 of the probes 10 as well as the guide hole plate 110 may be seated on the seating part 122 of the reference plate 120. Further, the plurality of probes 10 may be inserted into the different guide holes 130 to be erected by the seating part 122. At this time, if all the probes 10 inserted into the guide holes 130 have substantially the same height when upright, the planarity based on the tips 16 of the probes 10 may be fairly uniform when the probe card is implemented. It indicates that, in using the probe card, with the amount of overdrive applied to a conventional vertical probe card, all of the probes 10 may be effectively contact the chip pad of the wafer, for example, with an overdrive amount of 40 μm to 60 μm that is significantly smaller than 80 μm to 120 μm. The small amount of overdrive reduces damage on a chip and a pad and prolongs the life of the probe card.

Therefore, in order to improve the planarity of the probe card, good planarity of the seating part 122 is also beneficial. For example, in the case of 12-inch diameter seating part 122, the planarity may be 2 μm to 3 μm, more preferably 1 μm to 2 μm.

Hereinafter, each constitution of the jig 100 and the form of aligning the probes 10 will be described in detail with reference to the drawings.

The guide hole 130 is hollow communicating vertically from the upper surface to the lower surface including a first opening part 132 formed on the upper surface 116, a second opening part 134 formed in the lower surface 114, and an inner surface 118 extending between the outer perimeters of the first opening part 132 and the second opening part 134. All of the guide holes 130 formed in one guide hole plate 110 may have a cross section of one of a circle, a triangle, a rectangle and a square. The cross section may have the same shape and the same size, along the longitudinal direction of the guide holes 130.

The cross-sectional shape of the guide holes 130 is not particularly limited and may be appropriately designed according to the shape of the probes 10 to be inserted.

The probes 10 may be introduced into the guide holes 130 through first opening parts 132. Meanwhile, in order to prevent damage to the probes 10 during the introduction process and in order for the probes 10 to be introduced into the guide holes 130 through the first opening parts 132 smoothly along the slope, the outer periphery of the first opening parts 132 may be chamfered to have a tapered included structure. The surface constituting the inclined structure may be a flat surface or a curved surface.

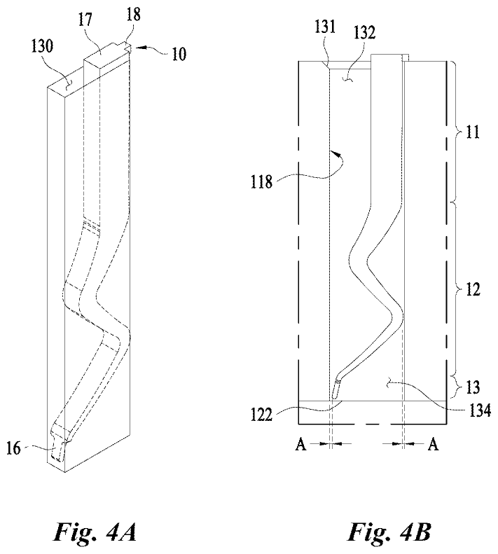

In order to implement such an introduction structure, the cross-sectional shape of the guide hole 130 may be, for example, a polygonal shape, an irregular polygonal shape, a circular shape, an oval shape, or an irregular shape in which these are combined. More specifically, the guide hole 130 forms only a minimum space into which the probe 10 may be vertically introduced. That is, the cross section of the guide hole 130 may have substantially the same shape as that of accumulated a plurality of cross-sections along the length direction of the probe 10, excluding the supporting part 18. For example, a cross section along the longitudinal direction of the probe 10 of FIGS. 4A and 4B corresponds to a rectangle, and in this case, the guide hole 130 also has a substantially same rectangular cross section and has a rectangular parallelepiped shape as a whole.

As such, the probe 10 introduced through the first opening part 132 may be lowered toward the second opening part 134 while in contact with at least a portion of the inner surface 118 of the guide hole 130. That is, the probe 10 is guided to move downward along the inner surface 118 of the guide hole 130. However, the complement engagement of the probe 10 with the inner surface 118 that sets the guide hole 130 may cause damage to the probe 10 during the insertion process. Thus, it may be desirable for each inner surface 118 to be spaced a predetermine distance with respect to the surface of the probe 10 it faces. Separation distance A may be 1 μm to 3 μm, specifically, 1 μm to 2 μm.

The probe 10 inserted into the guide hole 130 may maintain an upright state in the internal space, by the tip 16 of the probe 10 contacting the seating part 122 of the reference plate 120 through the second opening part 134 and being supported by the seating part 122.

Further, the supporting part 18 protruding outward is formed on a fore end 17 of the probe 10 of the present disclosure, and an area of the outer periphery of the first opening part 132 forms a supporting area 133 corresponding thereto. The supporting area 133 has a shape corresponding to the shape of the supporting part 18, and thus the supporting area 133 fixes the supporting part 18, to prevent the probe 10 from being drawn into the first opening part 132 because the supporting part 18 is struck downward by the load of the probe 10 or deviated to a side. Therefore, even in the case where the first opening part 132 has a chamfer for flexible insertion of the probe 10, it is beneficial that the chamfer is provided avoiding the supporting area 133.

The shape of the supporting area 133 being corresponded to the shape of the supporting part 18 may indicate that the lower surface of the supporting part 18 and the supporting area 133 abut. For example, when the supporting part 18 protrudes in the horizontal direction from the fore end 17 so that the lower surface of the supporting part 18 is formed horizontally to the ground, the supporting area 133 may also be formed horizontally to the ground.

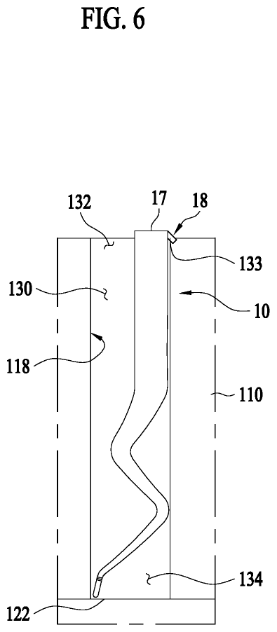

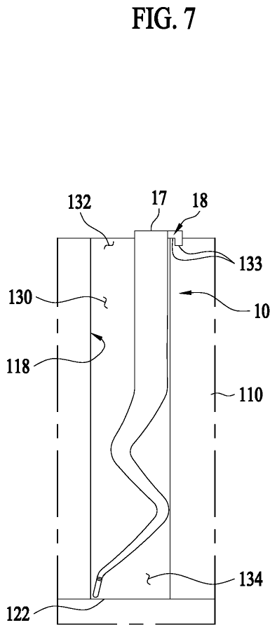

FIGS. 6 and 7 each illustrate another example embodiment of the supporting area 133 of the first opening part 132.

When the lower surface of the supporting part 18 forms an inclined surface or a curved surface facing the ground, it is beneficial that the supporting area 133 also forms an inclined surface or a curved surface corresponding to the shape. When the supporting part 18 forms the lower surface of the inclined surface or the curved surface, the risk of the probe 10 falling out of the seating part 122 and entering into the first opening part 132 may be fundamentally prevented.

As described above, when the supporting part 18 spans the supporting area 133, the downward force may no longer be applied in that state. That is, an upright height of the probe 10 is maintained, by the tip 16 being supported by the seating part 122 of the reference plate 120 and by the supporting part 18 spanning the supporting area 133 at the top. This may be equally applied to all probes 10. Since the probe 10 has a structure that is elastically deformable, the upright height may be changed by a force applied downward even if it is minute. However, since all the probes 10 should be arranged at the same upright height for the even planarity with respect to the tips 16 of the probes 10, the fact as described above that the upright height of the probes 10 may be kept constant is the major advantage of the jig 100 according to the present disclosure, and when a micro-electro-mechanical system (MEMS) technology is applied to the manufacturing process of the probe, the size of probes may be almost perfectly uniform.

Further, as the supporting part 18 spans the boundary of the first opening part 132, the supporting part 18 may protrude outside the first opening part 132. The protruding supporting part 18 may easily contact the circuit of the circuit board when the probe 10 is bonded to the circuit board of the probe card, and may be bonded in that state.

In an example embodiment regarding this, when the probe 10 is maintained in an uptight state, in order for a part on a side of the fore end 17 of the probe 10 to protrude through the first opening part 132, the depth of the guide hole 130 compared to the height of the upright probe 10 may be 85% to 99.9%, specifically 90% to 95%, and more specifically 92% to 93%. A stable bonding may be achieved only when a certain height is provided.

Referring back to FIGS. 1 to 5, the reference plate 120 and the guide hole plate 110 may be detachably coupled to each other. Here, a mechanical fastening method well known in the art may be considered for the coupling, for example, a fastening using a clamping member or a complementary engaging hook and a groove fastening method. However, the fastening method is not limited thereto.

In addition to the methods, the jig 100 according to the present disclosure includes a structure and a constitution in which the guide hole plate 110 and the reference plate 120 may be firmly fastened.

As an example embodiment regarding this, the guide hole plate 110 and the reference plate 120 may be coupled to each other by force generated by magnetism. In an example embodiment, the reference plate 120 may include the magnet 128, and the guide hole plate 110 may include a member or material that generates mutual attraction with the magnet 128, for example, a metal material. As a more specific example embodiment, a metal coating layer capable of being attracted to the magnet 128 may be formed on the lower surface 114 of the guide hole plate 110. Meanwhile, the lower surface 114 on which the metal coating layer is formed may be finished by a planarization process before the metal coating layer is formed, and this state, the metal coating layer may be plated.

In some cases, the guide hole plate 110 may be made of a magnetic material that itself may be attracted to a magnet. In this case, the metal coating layer may be omitted.

Accordingly, the magnet 128 of the reference plate 120 pulls the metal coating layer of the guide hole plate 110 in the vertical direction to bring the guide hole plate 110 into close contact with the reference plate 120. That is, the guide hole plate 110 and the reference plate 120 may be fixed to each other by the magnetic force of the magnet 128.

However, the metal coating layer may be absent on the inner surface 118 of the guide hole 130. This is not only facilitating the coating process of the metal coating layer, but it is also to prevent the possibility of interference caused by the plating of the inner surface 118 when the probe 10 enters the guide hole 130. Therefore, it is beneficial to form the guide hole 130 after the formation of the metal coating layer.

The metal coating layer may include one or more selected from the group consisting of nickel, iron, cobalt, tungsten and stainless steel, or an alloy of two or more selected from the group.

The magnet 128 is not particularly limited as long as it stably reveals a coercive force in a chamber of the high-temperature applied for bonding. However, specifically, the magnet 128 may be the alico magnet, the ferrite magnet or the samarium cobalt that reveals coercive force even at a temperature of 450° C. or higher, and a mixture thereof may be used.

The magnet 128 may also move the probe 10 introduced into the guide hole 130 by its magnetism to the seating part 122 and prevent a shaking of the probe 10 supported by the seating part 122. By the action of the magnet 128, the probe 10 is stably descended in the guide hole 130 and is fixed.

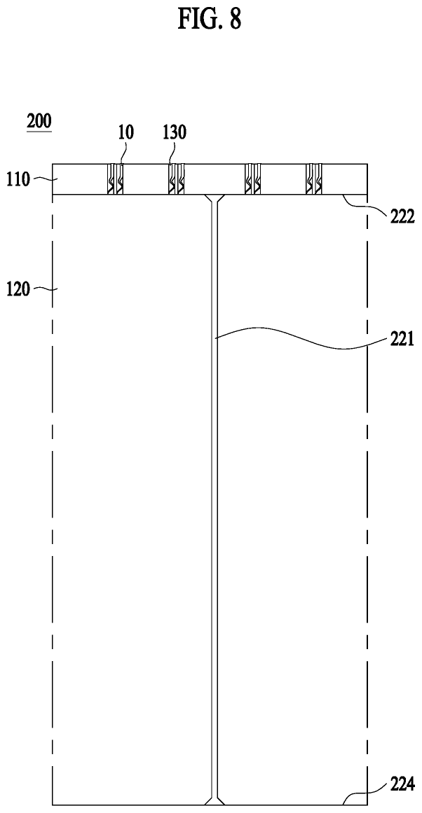

As another example embodiment, FIG. 8 is a vertical cross-sectional view of a jig 200 according to another example embodiment of the present disclosure.

The jig 200 illustrated in FIG. 8 shares substantially the same features and functions as the jig 100 as described above. However, the jig 200 has the difference that the reference plate 220 includes a plurality of inlets 221 communicating in the vertical direction from the seating part 222 to a bottom surface 224.

Each of the inlets 221 has one side open to the seating part 222, and the one side is located on the lower surface 214 of the guide hole plate 210 where the second opening part 234 of the guide hole 230 is absent. As such, when the inlet 221 is positioned, air may be sucked into from the other open side using an air drain device. At this time, a negative pressure is formed in the inlet 221, the guide hole plate 210 may be fixed while being more closely attached to the seating part 222 by the negative pressure formed in the inlet 221.

In the model in which the guide hole plate 210 and the reference plate 220 are detachably coupled to each other, only one of the magnet 228 and the inlet 221 described above may be selectively used. However, both the magnet 228 and the inlet 221 may be used in combination.

### Probe Alignment System

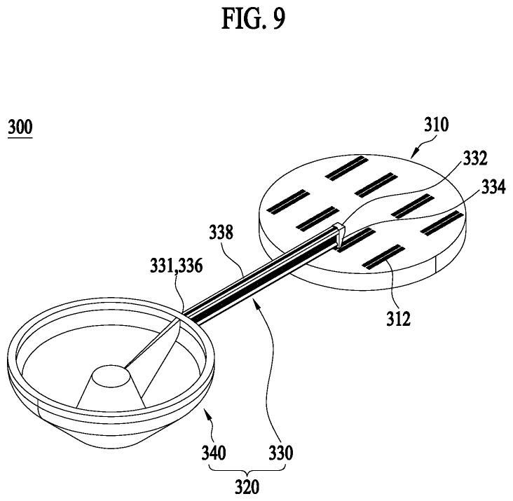

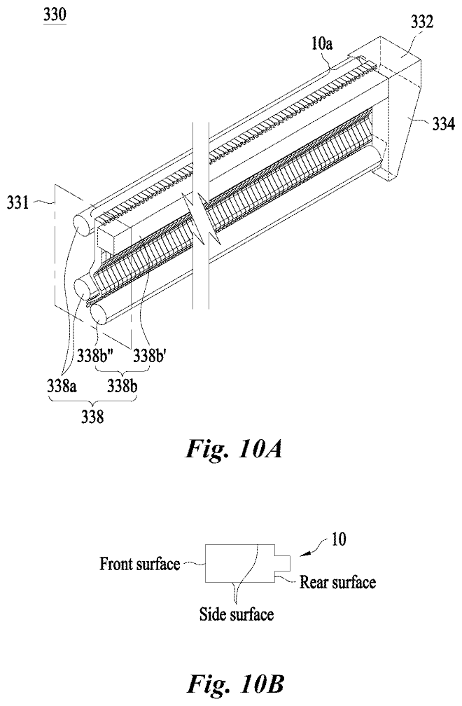

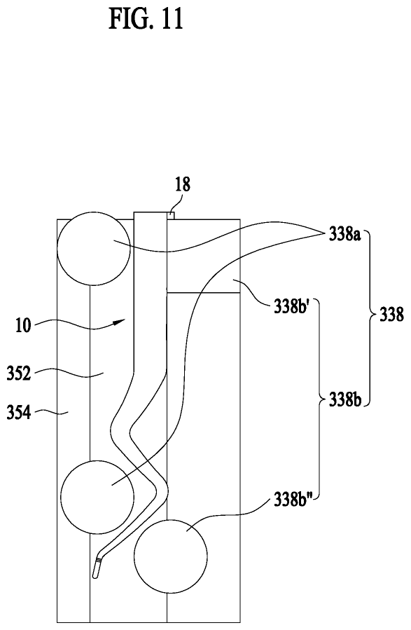

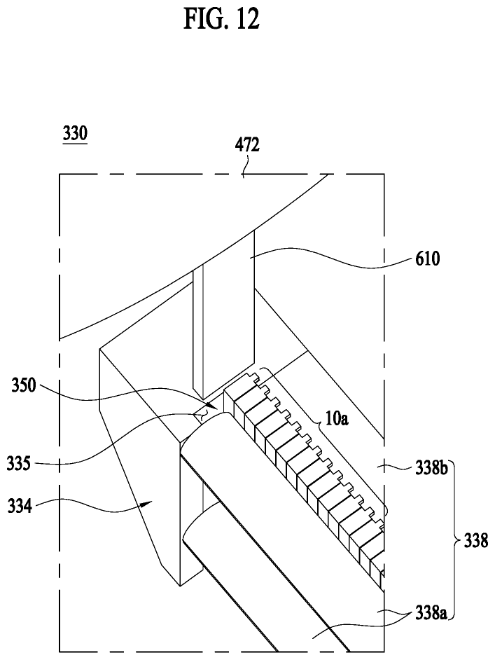

FIG. 9 schematically illustrates a probe alignment system 300 according to an example embodiment of the present disclosure. Further, FIGS. 10 to 13 schematically illustrate a magazine 330 of a probe storage 320.

Referring to the drawings together, the probe alignment system 300 includes a jig 310 and the probe storage 320.

The jig 310 is provided to accommodate a plurality of probes 10 in guide holes 312 formed at predetermined positions to make the probes 10 stand upright, and allow the probes 10 from the guide holes 312 to be coupled to the MPH (not illustrated) in the upright state.

Features related to the jig 310 may be at least partially the same as the structure, features and structural advantages of the jig 100 described with reference to FIGS. 1 to 8. Therefore, a detailed description of the jig 310 will be omitted in the description of the present disclosure.

The probe storage 320 is a member for storing the probes 10 in a predetermined arrangement so as to supply the probes 10 one by one to the guide holes 312 of the jig 310. The probe storage 320 includes the magazine 330 and a feeding part 340.

The probe storage 320 may accommodate a plurality of probes 10. The accommodated plurality of probes 10 may be arranged in a line in the upright state while facing the same direction. The arrayed plurality of probes 10 have a structure that may be sequentially supplied to each guide hole 312. Since the probe storage 320 accommodates the plurality of probes 10 in the upright state, the probes 10 may be inserted into the guide holes 312 in the upright state, and this provides an optimal state for repeatedly performing the operation of inserting the probes 10 into the guide holes 312. In particular, there is a synergistic effect of providing a space for inserting the probe 10 into the guide hole 312 through a physical, optical and electronic apparatus.

Hereinafter, for better understanding, when the magazine 330 is assumed to be a straight line, an end of the magazine 330 on the side where the feeding part 340 is located is referred to as one side 331 and the opposite end of the one side 331 is referred to as the other side 332.

The magazine 330 is configured to receive therein probe arrangement structure 10a in which the plurality of probes 10 are arranged in the upright state in the same direction. As illustrated in the drawings, the magazine 330 is connected to the feeding part 340 from the one side 331, and has a structure extending in the direction from the one side 331 to the other side 332. Thus, the magazine 330 may receive the plurality of probes 10 in a row in the longitudinal direction.

In particular, the probe 10 may be disposed and arranged in one direction so that the side surface faces the adjacent probe 10. Here, the term “side surface” refers to a side of the probe 10 based on the upright state in which the probe 10 is coupled to the MPH 20, and in particular, side surfaces may indicate two mutually parallel surfaces of the probe 10.

The feeding part 340 preliminarily establishes the orientation so that the plurality of probes 10 may be positioned in the arrangement in the magazine 330. The feeding part 340 is configured to continuously feed the probes 10 into the magazine 330 one by one. Although not separately illustrated in the drawing, the feeding part 340 may be a vibration feeder that supplies the plurality of probes 10 while aligning the probes 10 with vibration. The feeding part 340 such as the vibration feeder may arrange the plurality of probes 10 in a specific intended direction, and may supply the plurality of probes 10 one by one to the magazine 330 while maintaining the arrangement direction.

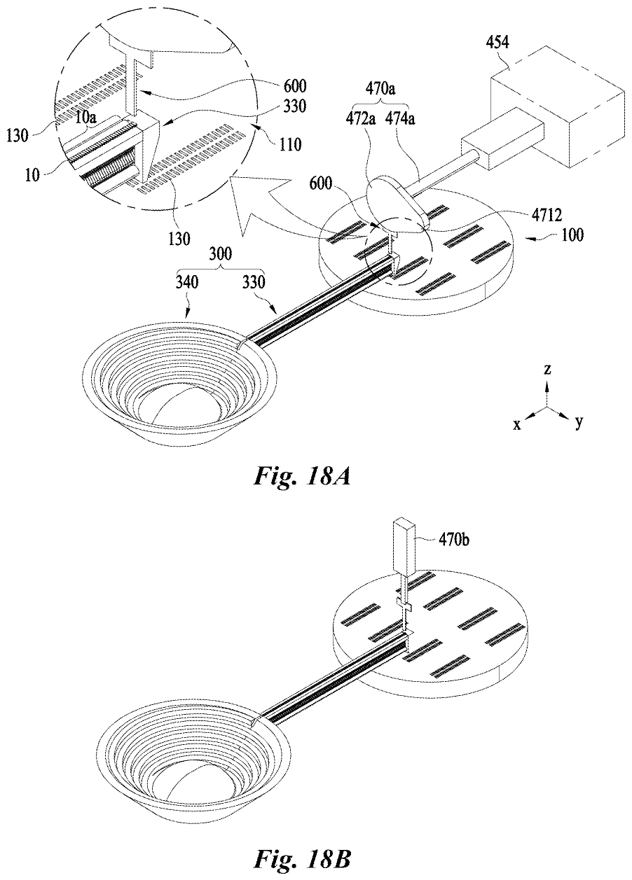

More specifically, in the present disclosure, a vacuum feeder may be a spiral vacuum feeder (see 340 of FIGS. 18A and 18B).

The one side 331 of the magazine 330 is connected to the feeding part 340 to receive the probe 10, and the other side 332 of the magazine 330 has a shape in which one probe 10 positioned at the outermost side may be separated to the outside and inserted into the guide hole 312. When the probe 10 is left from the other side 332 of the magazine 330, the feeding part 340 supplies the probe 10 to the magazine 330.

The probe 10 may be drawn downward by the mechanism from the other side 332 of the magazine 330 and directly inserted into the guide hole 312, or may be drawn upward and moved to the guide hole 312 to be inserted. A more specific mechanism will be described later.

Instead of the separated probe 10, the new probe 10 supplied from the feeding part 340 constitutes the probe arrangement structure 10a, and the probes 10 of the assembly are moved from the one side 331 to the other side 332. The adjacent probe 10 located on the side surface of the separated probe 10 moves to the position of the separated probe 10. The described aspect may be iteratively performed.

Among the above-described series of process, there may be have an error in recognizing the probe 10 in a first indented part 350 by a vision part 490 to be described later due to the vibration of the feeding part 340, and driving a probe carrier (see 600 in FIGS. 18A and 18B) also may be inappropriate. Therefore, in this stage, driving the feeding part 340 by operating software may be stopped.

The magazine 330 includes a side bearer 334 located on the other side 332, a connection part 336 located on the one side 331 and connected to the feeding part 340, and one or more support bodies 338 extending between the side bearer 334 and the connection part 336.

In an example embodiment, when the probe 10 is left from the other side 332 of the magazine 330, the probes 10 may be sequentially moved to the other side 332 by the probes 10 supplied from the feeding part 340. At this time, the probe 10 located at the end of the other side is supported in contact with an inner surface 352 of the side bearer 334, and the probe arrangement structure 10a may be pressed as the probes 10 supplied from the feeding part 340 move in the direction from the one side 331 to the other side 332. Therefore, the probe arrangement structure 10a may be pressed so that the side surface of the newly supplied probe 10 is in close contact with the inner surface 352 of the side bearer 334 to maintain the upright state arranged in a line in the lateral direction.

In another example embodiment, the connection part 336 may include a pressing means (not illustrated) for pressure from the one side 331 to the other side 332.

In this structure, when the probe 10 supplied from the feeding part 340 is supplied between the pressing means and the probe 10 adjacent thereto and the probe 10 is left from the other side 332 of the magazine 330, the pressing means may help the force of pressing the probe 10 supplied from the feeding part 340 in the direction from the one side 331 to the other side 332.

Accordingly, the probes 10 are sequentially moved to the other side 332 by the pressing means, the probe 10 positioned at an outermost side is supported in contact with the inner surface 352 of the side bearer 334, and the pressing means presses the probe 10 laterally. As a result, the magazine 330 may accommodate the probes 10 in the upright state in which the probes 10 of the probe arrangement structure 10a are arranged in a line while facing each other.

The pressing means may include at least one of a vibration feeder, a spring, a screw, a gear and a belt.

The support bodies 338 mechanically fix the side bearer 334 and the connection part 336, and at the same time, support the front and rear surfaces of the probes 10 when the probes 10 move from the one side 331 to the other side 332. Thus, the support bodies 338 guide the previously accommodated probes 10 to move while forming a line in the lateral direction.

The support bodies 338 include one or more front support bodies 338a facing the front surfaces of the probes 10 and one or more back support bodies 338b facing the rear surfaces of the probes 10.

In particular, the support bodies 338 are provided to correspond to the shape of the probes 10, and thus the support bodies 338 may also serve to prevent the feeding part 340 from moving the probe 10 disposed in a wrong direction to the magazine 330. That is, when the support bodies 338 are disposed in at least one area among areas other than the area where the probes 10 are desired to be arranged in the passage formed by the magazine 330, the probe 10 unintentionally oriented may be caught on the support bodies 338 and may not enter the passage of the magazine 330. Thus, the magazine 330 may serve to filter the probe 10 oriented in an unintended direction.

The support bodies 338 may be implemented in the form of a plurality of beams provided along the length direction of the passage of the magazine 330. In particular, when the probes 10 are arranged in one direction facing each other, the support bodies 338 are provided with the front support bodies 338a for supporting the front surfaces of the probes 10 and the back supporting bodies 338b for supporting the rear surfaces of the probes 10 to support both front and rear surfaces. The surfaces of the probe 10 supported by the front support bodies 338a and the back support bodies 338b are not necessarily front and rear, and thus the front support body 338a may be replaced with a first support body, and the back support body 338b may be replaced with a second support body. For convenience of description, the case of the front support bodies 338a and the back support bodies 338b will be described.

For example, the front support bodies 338a may be cylindrical beams having a substantially circular cross-sectional shape, and in detail, the front support bodies 338a may be a pair. One of the front support bodies 338a connects the side bearer 334 and the connection part 336 from the top of the magazine 330 so as to guide the probe 10 from the supper side adjacent to the fore end even in the front. The other one of the front support bodies 338a connects the side bearer 334 and the connection part 336 from the bottom of the magazine 330 to guide the probe 10 from the lower side adjacent to the tip even on the front side.

The front support bodies 338a have a relatively small area in contact with the front surface of the probe 10 based on the cylindrical structure, and thus contact resistance and damage of the probe 10 due to the contact may be reduced or minimized. One of the front support bodies 338a positioned at the bottom of the magazine 330 may be positioned in a bent part of the probe 10, and at this time, since the front support bodies 338a have curved surfaces, the bent part may be supported stably in response to the curved part.

The back support bodies 338b may include a cuboidal beam 388b′ that is substantially rectangular in shape in transverse cross-section and a cylindrical beam 388″.

The cuboidal beam 388b′, one of the back support bodies 338b, connects the side bearer 334 and the connection part 336 at the top of the magazine 330 to guide the probe 10 from the upper side adjacent to the fore end even from the rear surface.

The support bodies 338 may be formed by mechanical processing or by the MEMS process.

The probe 10 of the present disclosure is formed with the supporting part 18 protruding in the rear direction at the fore end, and thus the supporting part 18 may span the end of the cuboidal beam 388b′. Accordingly, the probe 10 may maintain the upright state without moving downward in a state in which the supporting part 18 spans the cuboidal beam 388b′.

The cylindrical beam 388″ that is one of the back support bodies 338b connects the side bearer 334 and the connection part 336 at the lower side of the magazine 330, to guide from the lower side adjacent to the tip even on the rear surface of the probe 10. One positioned at the bottom of the magazine 330 may be positioned at a bent part of the probe 10, and since the cylindrical beam 388″ has a curved part, the bent part may be stably supported by the curved part.

The side bearer 334 of the magazine 330 is indented in the direction from the one side 331 to the other side 332 to form the inner surface 352 of the side bearer 334, and the side bearer 334 includes the first indented part 350 forming an open outlet 335 at its top and bottom.

The first indented part 350 includes a first side surface 354 and a second side surface 356 each extending from both ends of the inner surface 352 together with the inner surface 352. The inner surface 352 is in contact with a side of the probe 10 positioned at an outermost side, the back surface of the probe 10 faces the first side surface 354, and the front surface of the probe 10 faces the second side surface 356.

Therefore, the first indented part 350 having the indentation depth equal to the width of the first side surface 354 and the second side surface 356 accommodates the probe 10 positioned at the outermost side. In the accommodated space, the support bodies 338 are not located, so the upward or downward movement of the probe 10 is not limited, and the probe 10 may be supported and fixed by a force pressed in contact with the inner surface 352 of the first indented part 350 or an attractive force by a slip preventing part 339 to be described later.

The probe 10 accommodated in the first indented part 350 may be separated through an upper outlet 3351 or a lower outlet 3352 while sliding upward or downward by an external force.

The slip preventing part 339 prevents unintended separation of the probe 10 from the first indented part 350. The probe 10 positioned at the end of the other side 332 of the probe arrangement structure 10a should be left from the magazine 330 only in an intended state, but a case in which the probe 10 is left from the magazine 330 through the upper outlet 3351 or the lower outlet 3352 may occur due to lack of pushing force from one side or gravity.

The slip preventing part 339 is provided at an end of the other side of the side bearer 334 in the form of a built-in magnet for generating mutual attractive force with the probe 10. The slip preventing part 339 prevents unintentional separation by pulling the probe 10 positioned at the end of the other side 332.

At this time, it is beneficial that the attractive force of the probe 10 generated by the slip preventing part 339 is designed to occur with a degree that does not interfere an intended external force to separate the probe 10.

In an example embodiment, if a probe carrier (see 600 of FIGS. 18A and 18B) in the form of a blade having a thickness less than the width of the first indented part 350 passes through the first indented part 350 while pushing the fore end of the probe 10 downward from the fore end side of the probe 10, the probe 10 slides downward while being guided by the inner surface 352 of the first indented part 350 to which the probe 10 abuts, the first side surface 354 and the second side surface 356. Eventually, the probe 10 may be released from the magazine 330 through the lower outlet 3352 of the side bearer 334.

In some cases, when the probe 10 moves downward, a groove 355 may be formed on the first side surface 354 of the first indented part 350 so that the supporting part 18 (see FIGS. 4A and 4B) formed at the fore end of the probe 10 may pass through without being caught on the rear surface of the first indented part 350. The groove 355 has a structure that extends from the top to the bottom of the side bearer 334.

In another example embodiment, when a member such as a collet capable of sucking in close contact with the fore end of the probe 10 may suck the probe 10 and then move upward, the probe 10 may slide upward while being guided by the inner surface 352 of the first indented part 350 in contact with the probe 10, the first side surface 354 and the second side surface 356, and eventually, the probe 10 may be left from the magazine 330 through the upper outlet 3351 of the side bearer 334.

A specific structure for allowing the probe 10 to be inserted into the guide hole 312 by disengaging the probe 10 through the upper outlet 3351 or the lower outlet 3352 will be described later.

### Probe Alignment Apparatus

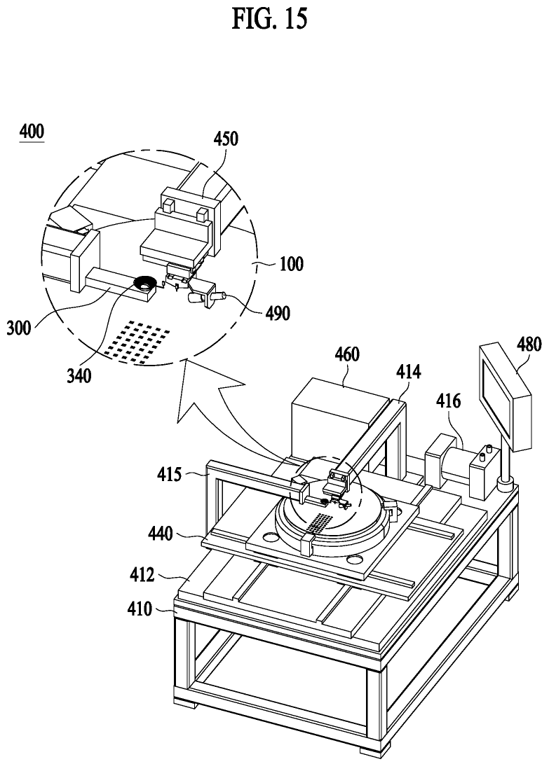

FIGS. 15 to 20 are schematic views of a probe alignment apparatus 400 and its respective components according to the present disclosure.

The probe alignment apparatus 400 includes the jig 100, the probe storage 320, the feeding part 340, a main frame 410, a vacuum pump 416, a plate 412, a fastening part 415, an arm member 414, a first stage 440, a second stage 450, an actuator 470, the vision part 490, a monitoring part 480, a controlling part 460 and a probe carrier 600 or 700.

The jig 100 and the probe storage 320 may have the same structures and configurations as those described with reference to FIGS. 1 to 14. Accordingly, a detailed description of the jig 100 and the probe storage 320 will be omitted below.

The main frame 410 is in the form of a frame formed by assembling a plurality of beams, and the main frame 410 is provided to support the other components, for example, the plate 412, the arm member 414, the jig 100, the probe storage 320, the first stage 440, the second stage 450, the actuator 470, the vision part 490 and the controlling part 460.

The plate 412 is a flat metal or plastic plate on which the first stage 440 on which the jig is mounted is stably seated. The plate 412 may be mechanically coupled to the first stage 440 in some case.

The arm member 414 is an arm mounted on the main frame 410 and vertically bent in “¬” shape as a whole so as to be spaced upwardly from the plate 412.

The arm member 414 includes a first arm 414a perpendicular to the plate 412 with respect to the plate 412. An end of the first arm 414a is mechanically coupled to the main plate.

The arm member also includes a second arm 414b extending from the other end of the first arm 414a. The second arm 414b is perpendicular to the first arm 414a and is substantially parallel to the plate 412 with respect to the plate 412. In an example embodiment, the arm member 414 may be a single member in which the first arm 414a and the second arm 414b extend integrally with each other. In another example embodiment, the arm member may be an assembly in which the first arm 414a and the second arm 414b are detachably mechanically fastened to each other.

When one end of the second arm 414b connected to the first arm 414a is defined as one side, the second stage 450 is mounted on the other end of the second arm 414b. Therefore, the second stage 450 and the first stage 440 are spaced apart from each other substantially corresponding to an upwardly extending length of the first arm 414a, and the second stage 450 and the first stage 440 face each other in the same area when viewed from above.

Further, as illustrated in the drawing, the probe storage 320 is positioned between the first stage 440 and the second stage 450. Therefore, the probe 10 positioned at the outermost side of the probe arrangement structure 10a stored in the probe storage 320 is also positioned between the first stage 440 and the second stage 450. The first stage 440 performs alignment so that the guide hole 130 into which the probe 10 positioned at the outermost side of the magazine 330 is to be inserted is positioned on the same line as the probe 10.

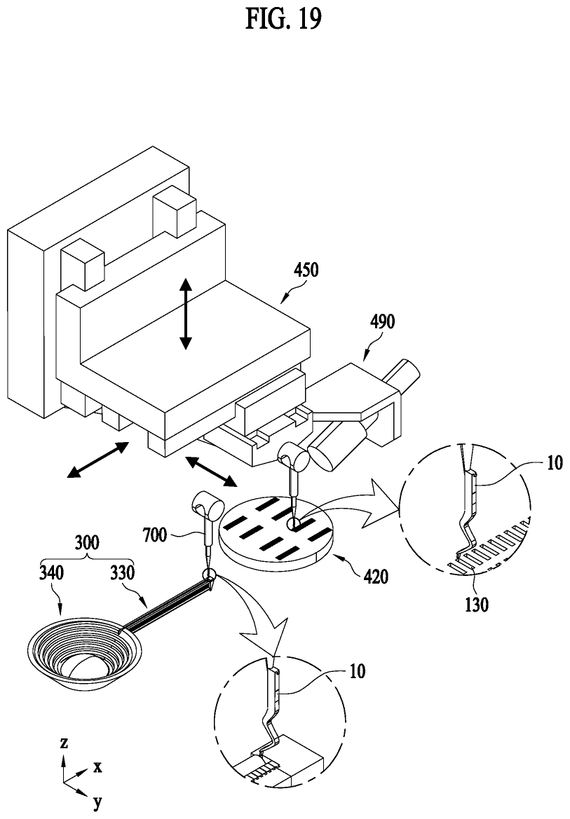

The actuator 470 drives the probe carrier 600 or 700 mounted on the actuator 470 so that the probe 10 at the outermost side is inserted into the guide hole 130. The actuator 470 may be implemented to rotate or reciprocate linearly to drive the probe carrier 600 (see FIGS. 18A and 18B), or the actuator 470 may also be implemented in the form of the second stage 450 that translates with respect to the x-axis, y-axis and z-axis to drive the probe carrier 700 (see FIG. 19).

In the present disclosure, the vision part 490 is configured to identify the tip and the fore end of the probe 10 arranged at the outermost side of the probe arrangement structure 10a accommodated in the probe storage 320, and provide information on a distance calculated by identifying coordinates of the guide hole 130 in which the probe 10 is to be inserted, to the controlling part 460 comprising the computer in which the predetermined program is embodied.

The vision part 490 may be provided in the form of an optical camera that acquires an image of a subject, or a sensor that senses a distance to a counterpart or shape. However, the vision part 490 is not limited the example embodiment.

The vision part 490 may allow a user or an internal system to identify the position of the probe 10, the relative position or application state of the probe 10 and the probe carrier 600 or 700, and the relative position or introduction of the probe 10 and the guide hole 130.

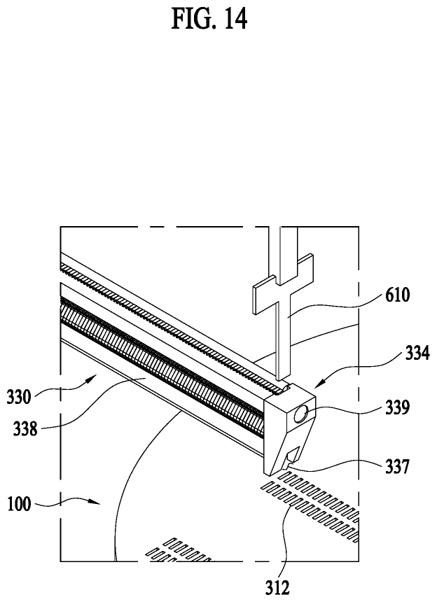

For example, referring to FIG. 14, in particular, the side bearer 334 may form a second indented part 337, in order for the vision part 490 to easily identify the relative position of the probe 10 and the magazine 330, more specifically, to easily identify whether the probe 10 is properly withdrawn from the first indented part 350.

Accordingly, the second indented part 337 has a structure indented in the direction of the end facing an upper end adjacent to the outlet and/or a lower end adjacent to the outlet 335 so that the fore end or the tip of the probe 10 accommodated in the first indented part 350 is exposed to the outside.

The monitoring part 480 is a member functioning in connection with the above-descried vision part 490, and the monitoring part 480 may display, for example, an image identified by the vision part 490 with an enlarged screen. Therefore, a user may easily identify the extremely fine size of the probe with the naked eye.

The controlling part 460 may process the information provided from the vision part 490 to determine whether the probe carrier is accurately located at the position of the probe at an outermost side among the probes. Further, the controlling part 460 transmits a driving signal to the first stage 440, the second stage 450 or the actuator 470, based on an internal operation result or an externally input signal.

The fastening part 415 is a member that is fastened to the probe storage 320 to fix the probe storage 320. The fastening part 415 may be coupled to any part of the probe alignment apparatus 400 so that the probe storage 320 maintains the fixed state at a predetermined position.

FIG. 15 illustrates that the fastening part 415 is fastened to the main frame 410 to fix the probe storage 320 at a predetermined position, but it is only an example embodiment for better understanding. The fastening part 415 may be fastened not only to the main frame 410 but also to the plate 412, for example, the second stage 450 to fix the probe storage 320.

Further, in FIG. 15, the fastening part 415 is illustrated in the shape of the “¬” but it is only an example for better understanding. The shape of the fastening part 415 is not limited thereto. It should be understood that the shape of the fastening part 415 may vary depending on a desired fastening position, according to a part where the probe storage 230 is to be located, or according to a need in consideration of the convenience of fastening.

In summary, all operations of the probe alignment apparatus 400 are identified and recognized by the vision part 490, and the controlling part 460, with identification and recognition by the vision part, controls the insertion of the probe 10 into the guide hole 130 of the jig 100 to proceed sequentially according to a program including predetermined information and test coordinate insertion order and a control logic thereof.

In the present disclosure, the first stage 440 is a member on which the jig 100 of the present disclosure is detachably mounted, and the first stage 440 moves so that the jig 100 and the guide hole 130 formed therein may be aligned to an intended arbitrary position, while the first stage 440 itself rotating left, right and axis (x, y or θ).

In particular, the first stage 440 is characterized in aligning the jig 100 with the desired guide hole 130 to the position of the probe to be discharged from the probe storage 320.

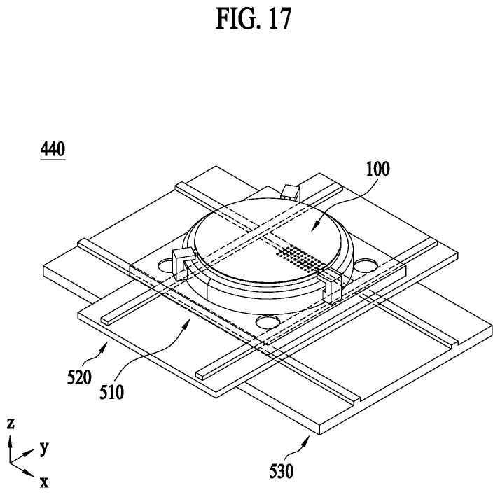

In this regard, the structure of the first stage 440 is illustrated in FIG. 17. Referring to FIG. 17, the first stage 440 is equipped with the jig 100, and includes a θ-axis driving part 510 for rotating the jig 100 in the θ direction, a Y-axis driving part 520 for moving the jig 100 with respect to Y-axis and an X-axis driving part 530 for moving the jig 100 with respect to X-axis.

Based on the ground, the X-axis driving part 530, the Y-axis driving part 520 and the θ-axis driving part 510 may be sequentially stacked upward.

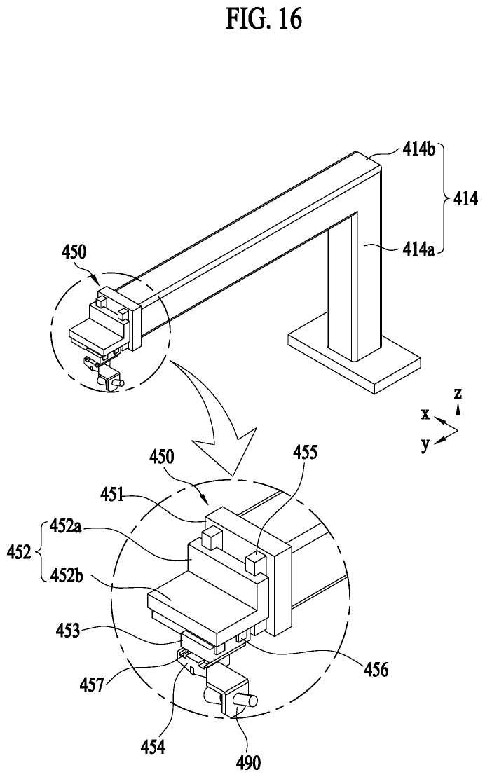

FIG. 16 schematically illustrates the second stage 450 mounted on the arm member 414.

Referring to FIG. 16, the second stage 450 includes two or more first guide rails 455 extending along the Z-axis. The second stage 450 includes a first plate 451 that is detachably mounted to the arm member 414.

The second stage 450, complementarily engaged with the first guide rails 455, further includes a second plate 452, which includes a vertical part 452a configured to slide along the first guide rails 455 in the Z-axis direction, and a horizontal part 452b extending vertically from the lower end of the vertical part 452a in the Y-axis direction and having two or more second guide rails 456 extending in the X-axis at the bottom.

The second stage 450 further includes a third plate 453 is complementarily engaged with the second guide rails 456 and is configured to slide along the second guide rails 456 in the X-axis direction and has two or more third guide rails 457 embodied at the lower end extending along the Y-axis, and a fourth plate 454 that is complementarily engaged with the third guide rails 457, configured to slide along the third guide rails 457 in the Y-axis direction, and includes an actuator mounted on the lower end and the vision part 490 mounted on the side surface.

In this structure, the vision part 490 is mounted on a side surface of the fourth plate 454 corresponding to the X-axis, and in the direction of the X-axis, the vision part 490 is configured to identify a tip and a fore end of the probe 10 arranged at an outermost side of the probe arrangement structure 10a accommodated in the probe storage 320 and is configured to provide information on a distance calculated by identifying coordinates of the guide hole 130 in which the probe 10 is to be inserted, to the controlling part 460 comprising the computer in which the predetermined program is embodied.

The controlling part 460 may determine whether the probe carrier 600 is accurately positioned at the position of the probe 10 arranged at the outermost side of the probe arrangement structure 10a.

In some cases, the feeding part 340 of the probe storage 320 may be mechanically fastened to the side of the vertical part 452a of the second plate 452 by a bracket (not illustrated). In this case, the probe storage 320 may move along the Z-axis in response to the Z-axis movement of the second plate 452.

The actuator 470 mounted on the fourth plate 454 may be a cam motion actuator 470a including a rotation shaft and a cam, or an actuator 470b that moves up and down.

FIGS. 18A and 18B illustrate schematic views of the actuators according to the example embodiments of the present disclosure.

Referring to FIG. 18A, the actuator 470a includes a rotation shaft 474a and a cam 472a. The cam 472a may be implemented as a plate-shaped member having different lengths from the axis of rotation to a plurality of end points. According to the rotation of the rotation shaft 474a provided in the horizontal direction and the cam 472a having different radii connected thereto, the probe carrier 600 engaged with the cam 472a moves up and down. In particular, when the probe carrier 600 moves vertically downward, the probe 10 is withdrawn.

An elastic restoring force with respect to the vertical upward direction may act on the probe carrier 600.

Referring to FIG. 18B, the actuator 470 is the actuator 470b that moves up and down, unlike the actuator 470a that rotates. The force transmission mechanism is different, but the principle of inserting the probe 10 into the probe carrier 600 is substantially the same.

Further, the probe carrier 600 may be in the form of “T”-shaped plate blade that easily pushes the probe 10 arranged at the outermost side accommodated in the probe storage 320 downward. The blade shape is illustrated as an example embodiment in the drawing, but a rod-shaped pin or a polygonal pin may alternatively be used.

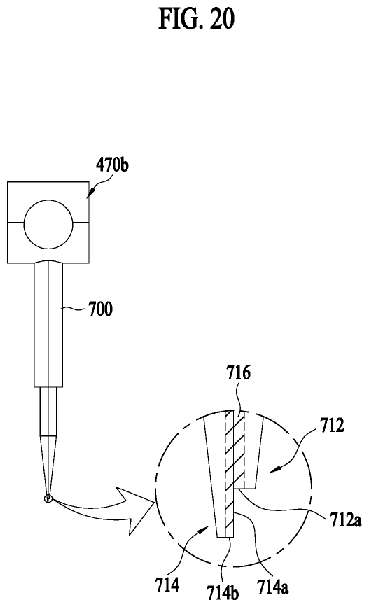

The probe carrier 600 of the type is illustrated in FIGS. 18A and 18B, but it is merely an example embodiment to help understanding, and is not limited thereto. The probe carrier 700 in the form of an inhaler illustrated in FIGS. 19 and 20 may also be provided. The probe carrier 700 is configured to form a negative pressure inside in a state in which the probe carrier 700 is in surface contact with the fore end of the probe 10 so as to separate the probe 10 upward from the probe storage 320 while sucking and fixing the probe.

Specifically, the probe carrier 700 includes a first end 712 and a second end 714 for sucking the fore end of the probe 10 in two directions. A suction hole 716 is formed over the first end 712 and the second end 714.

The first end 712 includes a first sucking boundary 712a partially open. The second end 714 includes a second sucking boundary 714a partially open. The first sucking boundary 712a and the second sucking boundary 714a form an open portion of the suction hole 716, and when the probe abuts the first sucking boundary 712a and the second sucking boundary 714a, respectively, the suction hole 716 is substantially or actually sealed.

The first sucking boundary 712a of the first end 712 and the second sucking boundary 714a of the second end 714 may be perpendicular to each other to correspond to the shape of the fore end corner area of the probe 10. That is, the first sucking boundary 712a of the first end 712 may suck the upper surface of the fore end of the probe 10, and the second sucking boundary 714a of the second end 714 may suck a side surface of the fore end of the probe 10.

In addition, the second end 714 further includes a distal end 714b. In a state where the second sucking boundary 714a is in contact with the side surface of the probe 10 and the first sucking boundary 712a is contact with the upper surface of the probe 10, the suction hole 716 is sealed inside by the first sucking boundary 712a blocked by the upper surface of the probe 10, the second sucking boundary 714a blocked to the side of the probe 10 and the distal end 714b of the self-closing structure. Therefore, the suction hole 716 acts to stably suck the probe 10 when the negative pressure is formed therein.

In other words, the above-described special structure of the probe carrier 700 allows the probe 10 to be stably fixed by simultaneously sucking the side and top surfaces of the probe 10. For example, when the probe 10 receives an external force tilting with respect to the probe carrier 700, the probe 10 has a high resistance and does not easily come off.

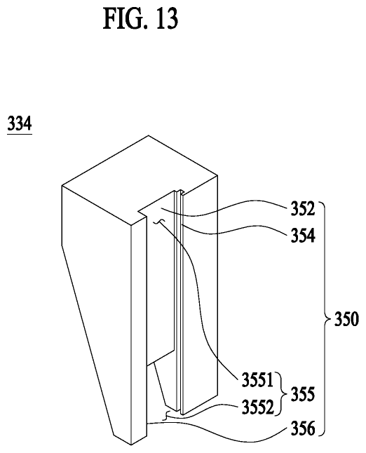

Further, the second end 714 may move to an inner area of the first indented part 350 (see FIG. 13) of the probe storage 320 to hold the probe 10. Thus, whether the probe 10 and the probe carrier 700 are in contact may be clearly recognized.

The series of the operations may be operated while being identified by the vision part 490 and the system operation program.

In this regard, as described above, the vision part 490 is a part that may allow a user or an internal system to identify the position of the probe 10, the relative position or application state of the probe 10 and the probe carrier 600 or 700, and the relative position or introduction of the probe 10 and the guide hole 130. Accordingly, for the effective operation of the vision part 490, the vision part 490 may be configured to observe the probe carrier 600 or 700 and/or the fore end and the tip of the probe 10 in the lateral direction of the probe carrier 600 or 700.

In this aspect, the vision part 490 may be mounted on the Y-axis actuator to identify the tip and the fore end of the probe 10 arranged at the outermost side of the probes 10 accommodated in the probe storage 320, and provide information the information regarding the distance calculated by identifying the coordinates of the guide hole 130 into which the probe 10 to be inserted, to the controlling part 460 including a computer in which a predetermined program is embedded.

However, it is a mere example embodiment. The mounted position and provided direction of the vision part 490 may be sufficiently varied according to interference with other components and arrangement of other components.

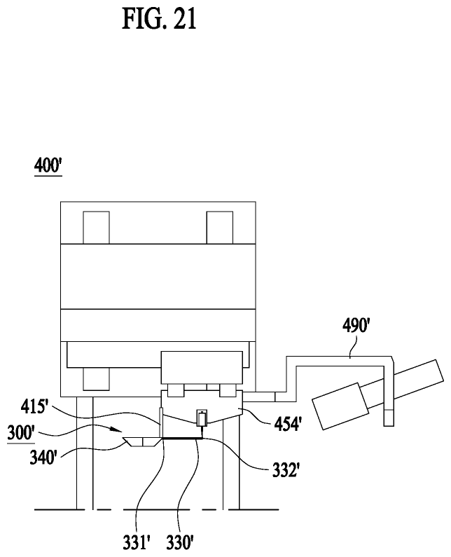

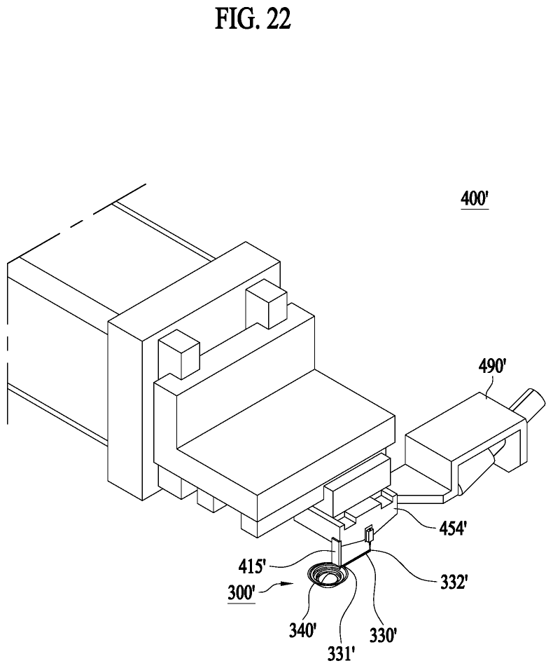

FIGS. 21 and 22 illustrate a probe alignment apparatus 400′ according to other example embodiments of the present disclosure. The probe alignment apparatus 400′ as illustrated in FIGS. 21 and 22 includes the same features as the probe alignment apparatus 400 described with reference to FIGS. 15 to 20, except for the probe storage 300′, and the structure is also the same.

In consideration of the shape or arrangement of at least one of the other components of the jig 100 or the probe alignment apparatus 400, the probe storage 300′ or a magazine 330′ may need to be provided more upwardly than in the previous example embodiments.

In the example embodiment implementing this, the probe storage 300′ illustrated in FIGS. 21 and 22 includes the magazine 330′ and a feeding part 340′ as in the previous example embodiments. The feeding part 340′ is positioned on one side 331′ of the magazine 330′ and the probe 10 is left from the other side 332′ to be inserted into the guide hole 130. The feeding part 340′ is connected from the one side 331′ of the magazine 330′ and a part of it is mechanically fastened to a fastening part 415′. In this state, the fastening part 415′ is connected to the other side opposite to the side surface of the fourth plate 454′, that is, as illustrated in the drawings, the side surface of the fourth plate 454′ to which a vision part 490′ is fastened.

### Method for Manufacturing a Probe Card

A method for manufacturing a probe card according to the present disclosure may include the following steps. However, an order to be described is only an example, and the manufacturing process does not proceed only in the order to be described.

After identifying predetermined semiconductor pad coordinate information, an operating program of the probe alignment apparatus is prepared in operation 1.

A main circuit board and the MPH for inspection of a wafer or a semiconductor chip as an inspection object having a predetermine pad arrangement are designed and manufactured in operation 2.

A plurality of probes for contacting a test circuit of the wafer or the semiconductor chip having predetermined test coordinates are produced in operation 3.

Guide holes are formed in a guide hole plate at portions of the test coordinates, and the guide hole plate is coupled to a reference plate in operation 4.

The probes are inserted into the plurality of guide holes respectively, formed at positions corresponding to the test coordinates, in operation 5.

A conductive paste adhesive is applied to each circuit pad of the MPH in operation 6.

The MPH is aligned with the guide hole plate so that the probes inserted corresponding to the test coordinates and the circuit of the MPH formed corresponding to the test coordinates face each other in operation 7.

The MPH is lowered to the top surface of the hole plate so that the top of the probes and the circuit of the MPH are contact and the plurality of probes are bonded to the circuit upright in operation 8.

A reflow process is performed on the bonded circuit and the probes to bond the circuit and the probes in operation 9.

A magnet of the reference plate, the reference plate and the guide hole plate are separated from the MPH to which the probes are coupled, and the MPH is connected to the main printed circuit board through the interposer in operation 10.

Electrical components are provided to match the device characteristics to the main printed circuit board, and the mechanical reinforcement is assembled in operation 11.

In operation 2, the manufacturing the probe tip may be performed according to the following steps.

A sacrificial film and a mold film are sequentially formed on a board.

A molding pattern is formed, having openings that exposes an upper surface of the sacrificial film while setting the shape of the probe by patterning the mold film.

A plurality of probes are formed in the molding pattern to fill the openings by a plating method.

The probes are lifted off by sequentially removing the molding pattern and the sacrificial film.

In the method, the sacrificial film may be a metallic material film containing copper. The mold film may be at least one selected from a photoresist film, a silicon oxide film, a silicon nitride film, a silicon oxynitride film and an SOG film. The conductive probe may be a metallic material film having etch selectivity with respect to the sacrificial film, such as copper, nickel, cobalt, rhodium, or an alloy thereof. Further, rhodium, palladium, copper, or an alloy thereof with good conductivity and abrasion resistance may be formed integrally with a prat of the tip of the probe through an interlayer process.

In operation 4, an inhaler or tweezers may be used, or an automatic inserter that recognizes the coordinates at which a guide hole is formed and moves to the coordinates to introduce the probe tip into the guide hole may be used. However, the present disclosure is not limited thereto.

### Probe Card

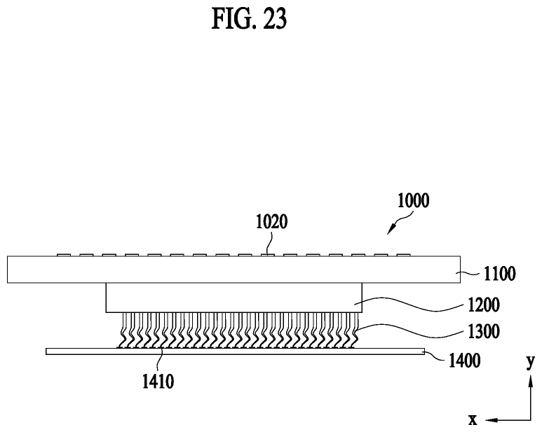

FIG. 23 illustrates a probe card according to the present disclosure.

Referring to FIG. 23, a probe card 1000 includes a main circuit board 1100, an interposer (not illustrated), an MPH 1200 and probes 1300.

A plurality of connectors 1020 are formed on the main circuit board 1100 to connect to, for example, a probe station (not illustrated) for inspecting electrical characteristics of a chip pad, and the main circuit board 1100 is coupled to the MPH 1200 on the other side of the surface on which the connector 1020 is formed.

The probe 1300 is arranged at a position corresponding to the position of the chip pad 1410 formed on the wafer 1400 on one side of the MPH 1200 facing the probe card 1000 in the Y-axis direction. Although not illustrated in the drawings, the MPH 1200 includes a plurality of interposers, and the interposers are configured to electrically connect the connector 1020 of the main circuit board 1100 and each of the probes 1300.

### MODE FOR CARRYING OUT THE DISCLOSURE

Although the above has been described with reference to the example embodiments of the present disclosure, those of ordinary skill in the art to which the present disclosure pertains will be able to make various applications and modification within the scope of the present disclosure based on the above content.

### INDUSTRIAL APPLICABILITY

The above described features may be partially or wholly applied to the field of a fig for manufacturing a probe card, a probe alignment system including the same and a probe card manufactured using the same.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A jig of manufacturing a probe card, the jig which is configured to make a plurality of probes upright at predetermined positions and to couple the probes to a micro probe head (MPH) in an upright state at the predetermined positions, and comprises:
a guide hole plate having test coordinates corresponding to positions of a plurality of pads arranged on a wafer or a semiconductor chip, and having a plurality of guide holes respectively accommodating the probes at positions of the test coordinate; and
a reference plate that the guide hole plate is detachably coupled on, that tips of the probes introduced through the guide holes are seated on, and that supports the probes in the upright state along with the guide holes,
wherein the guide hole plate induces introduction and separation of the probes along inner surfaces of the guide holes, so that the probes introduced into the guide holes are bonded to the MPH at the positions and then separated along the guide holes.

2. The jig of claim 1, wherein the guide hole plate includes a lower surface that is closest to a ground when positioned parallel to the ground, an upper surface opposite to the lower surface, and a side surface extending along outer periphery of the supper surface and the lower surface and connecting the upper surface and the lower surface,
wherein the guide hole is hollow communicating vertically from the upper surface to the lower surface including a first opening part formed on the upper surface, a second opening part formed on the lower surface and an inner surface extending between outer periphery of the first opening part and the second opening part, and
wherein the reference plate is closely attached to the lower surface to seal the second opening part so that a probe introduced through the first opening part does not pass through the second opening part and be left from the guide hole plate, and sets an internal space of an open shape with only the first opening part together with the inner surface.

3. The jig of claim 2, wherein the probe introduced through the first opening part is lowered toward the second opening part while in contact with at least a part of the inner surface.

4. The jig of claim 2, wherein a supporting part protruding outwardly from a fore end of the probe spans one area of the outer periphery of the first opening part.

5. The jig of claim 2, wherein all guide holes formed in the one guide hole plate have a same shape of one of a circle, a triangle, a square and a rectangle, and have a same shape and area in transverse cross section from the first opening part to the second opening part.

6. The jig of claim 2, wherein when the probe is inserted into the guide hole, a tip of the probe is in contact with the reference plate through the second opening part to be maintained in an upright state in the internal space.

7. The jig of claim 6, wherein when the probe is maintained in the upright state, a depth of the guide hole relative to a total height of the upright probe is about 70% to 99.9% so that a part of the fore end side of the probe protrudes through the first opening part.

8. The jig of claim 2, wherein a metal coating layer that is attracted to a magnet is formed on the lower surface of the guide hole plate, the metal coating layer being absent in the inner surface of the guide hole, and
wherein the metal coating layer includes at least one selected from a group consisting of nickel, iron, cobalt, tungsten and stainless steel, or an alloy of two or more selected from the group.

9. The jig of claim 2, wherein the guide hole plate comprises a magnetic body that is attracted to a magnet.

10. The jig of claim 2, wherein the guide hole plate comprises a material that is not attracted to a magnet.

11. The jig of claim 2, wherein at least a part of the outer periphery of the first opening part is chamfered to have a tapered inclined structure.

12. The jig of claim 1, wherein the guide hole plate and the reference plate are each made of a material having a thermal expansion coefficient of 90% to 100% with respect to the MPH or the wafer or the semiconductor chip in which a circuit for inspecting the wafer or the semiconductor chip is formed.

13. (canceled)

14. The jig of claim 2, wherein the reference plate comprises:
a seating part in which the guide hole plate is seated in a state of facing the lower surface of the guide hole plate;
a bottom surface that is opposite to the seating part;
a magnet built-in part in the reference plate, in which one or more magnets are formed in order for magnetic force to act evenly on all of the seating part of the reference plate; and
a magnet detachably mounted to the magnet built-in part.

15. The jig of claim 14, wherein the reference plate further comprises one or more inlets communicating in a vertical direction from the seating part to the bottom surface.

16. The jig of claim 15, wherein each of the inlets has one open side formed in the seating part that is located on the lower surface of the guide hole plate where the second opening part of the guide hole does not exist, and takes air into the other open side to form a negative pressure therein, and
the guide hole plate is close contact with the seating part by the negative pressure formed in the inlet.

17. The jig of claim 14, wherein the magnet pulls the guide hole plate in a vertical direction to closely contact the seating part, and
the guide hole plate and the reference plate are fixed to each other by the magnetic force of the magnet.

18. The jig of claim 14, wherein the magnet maintains magnetic force at a temperature of 400 degrees Celsius (° C.) or higher, moves the probe introduced into the guide hole by magnetism at room temperature to the seating part and prevents a shaking of the probe supported by the seating part.

19. The jig of claim 14, wherein the magnet loses its magnetic force at a temperature of 300° C. or higher, moves the probe introduced into the guide hole by magnetism at room temperature to the seating part, and prevents a shaking of the probe supported by the seating part.

20. The jig of claim 1, further comprising a clamping member for mechanically fixing the guide hole plate and the reference plate.

21. A probe alignment system comprising:
a jig configured to align probes so that a plurality of probes are accommodated in guide holes formed at predetermined positions to make the probes stand upright and the probes are coupled to the MPH from the guide holes in an upright state; and
a probe storage configured to accommodate one or more upright probes arranged in one direction and supply the probes to the guide holes so that the probes are inserted into the guide holes in an upright state.

22-31. (canceled)

32. A probe alignment apparatus comprising:
a main frame as a frame with a plurality of beams assembled;
a vacuum pump detachably mounted to the main frame;
a plate with rectangular shape detachably mounted to the main frame;
an arm member detachably mounted on the main frame and comprising a first arm extending in a direction perpendicular to the plate and a second arm extending in parallel to the plate while being perpendicular to the first arm;
a jig provided in the main frame to align the probes so that the plurality of probes are accommodated in guide holes formed at predetermined positions to make the probes stand upright, and from the guide holes, the probes are bonded to the MPH in an upright state;
a probe storage that accommodates a plurality of upright probes arranged in a line in one direction so that the probes are inserted into the guide holes in an upright state, and is positioned so that the probes are supplied to the guide holes;
a first stage mounted on the plate of the main frame to align the jig to the insertion position of a probe to be discharged from the probe storage in an arbitrary guide hole by moving the jig left and right, forward and backward, and rotating axially;
a probe carrier configured to insert a probe positioned at an outermost side among probes accommodated in the probe storage into the guide hole;
an actuator to which the probe carrier is mounted and which moves the probe carrier;
a second stage to which the actuator is mounted in a state of being mounted on the arm member, and that moves the probe carrier mounted on the actuator to an insertion or extraction position of a probe to be ejected from the probe storage by moving the actuator back and forth, left and right and up and down;
a fastening part configured to mechanically mount the probe storage to the main frame or the second stage;
a vision part configured to identify the probe arranged at the outermost side among the probes accommodated in the probe storage and a guide hole where the probe to be inserted;
a monitoring part configured to display an image identified by the vision part; and
a controlling part comprising a computer in which a predetermined program is embodied to control operations of the jig, the first stage, the second stage, the actuator, the vision part, the monitoring part, or the probe storage and a coordinate movement of the input guide hole.

33-43. (canceled)

44. A method of manufacturing a probe card, the method comprising:
fabricating probes;
preparing and combining a guide hole plate and a reference plate;
entering coordinates of a plurality of guide holes to insert the probes and the insertion order;
inserting a plurality of probes for contacting a test circuit of a wafer or semiconductor chip having predetermined test coordinates into a plurality of guide holes formed at positions corresponding to the test coordinates, respectively;
preparing a MPH in which a plurality of circuits for inspecting the wafer or semiconductor chip are formed at the positions corresponding to the test coordinates;
adding a conductive paste adhesive to each circuit of the MPH;
aligning the MPH with the guide hole plate so that fore ends of the probes inserted to correspond to the test coordinates and the circuits of the MPH formed to correspond to the test coordinates face each other;
manipulating the plurality of probes to be adhered upright on the circuits of the MPH by facing and contacting the MPH with an upper end surface of the guide hole plate so that the fore ends of the probes and the circuits of the MPH are in contact;
performing a reflow process on the adhered circuit and the probes to bond the circuit and the probes;
sequentially separating a magnet, the reference plate, and the guide hole plate from the MPH to which the probes are bonded;
coupling the MPH with a main printed circuit board, the MPH and the main printed circuit board being electrically interconnected by electronic components and interposers; and
attaching a plurality of connectors for connecting a plurality of electrical components corresponding to characteristics of the wafer or semiconductor chip to be tested and the probe card and a probe station, and fastening the deformation prevention mechanism apparatus.

45. A vertical micro-electro-mechanical systems (MEMS) probe card manufactured using the method of claim 44.
